(19) United States
(12) Patent Application Publication
(10) Pub. No.: US 2015/0162495 A1
(43) Pub. Date: Jun. 11, 2015

(54) SEMICONDUCTOR LIGHT-EMITTING DEVICE

(71) Applicant: Panasonic Intellectual Property Management Co., Ltd., Osaka (JP)

(72) Inventors: Akira INOUE, Osaka (JP); Toshiya YOKOGAWA, Nara (JP); Atsushi YAMADA, Osaka (JP); Masaki FUJIKANE, Osaka (JP)

(21) Appl. No.: 14/565,572

(22) Filed: Dec. 10, 2014

Related U.S. Application Data
(63) Continuation of application No. 13/818,167, filed on Feb. 21, 2013, now abandoned.

(30) Foreign Application Priority Data
Apr. 6, 2011 (JP) 2011-084807

(51) Int. Cl. H01L 33/20; H01L 33/18; H01L 33/32

(52) U.S. Cl. CPC H01L 33/20; H01L 33/32; H01L 33/18

(57) ABSTRACT

A nitride semiconductor light-emitting element 300 is a nitride semiconductor light-emitting element which has a multilayer structure 310, the multilayer structure 310 including an active layer which is made of an m-plane nitride semiconductor. The multilayer structure 310 has a light extraction surface 311a which is parallel to an m-plane in the nitride semiconductor active layer 306 and light extraction surfaces 311b which are parallel to a c-plane in the nitride semiconductor active layer 306. The ratio of an area of the light extraction surfaces 311b to an area of the light extraction surface 311a is not more than 46%.

### TECHNICAL FIELD

The present invention relates to a nitride semiconductor light-emitting element which has a multilayer structure including an active layer made of an m-plane nitride semiconductor. The present invention also relates to a semiconductor light-emitting device which includes a sealing portion that covers the nitride semiconductor light-emitting element.

### BACKGROUND ART

A nitride semiconductor containing nitrogen (N) as a Group V element is a prime candidate for a material to make a short-wave light-emitting device because its bandgap is sufficiently wide. Among other things, gallium nitride-based compound semiconductors have been researched and developed particularly extensively. Blue light-emitting diodes (LEDs), green LEDs, and semiconductor laser diodes which are made of gallium nitride-based semiconductors have already been used in actual products.

Hereinafter, the gallium nitride-based compound semiconductors are mainly described. The nitride semiconductors include a compound semiconductor in which some or all of gallium (Ga) atoms are replaced with at least one of aluminum (Al) and indium (In) atoms. Such a compound semiconductor is represented by formula AlₓGa_{y}In_{z}N (0≦x, y, z≧1, x+y+z=1).

By replacing Ga atoms with Al atoms, the bandgap can be greater than that of GaN, by replacing Ga atoms with In atoms, the bandgap can be smaller than that of GaN. This enables not only emission of short-wave light, such as blue light or green light, but also emission of orange light or red light. Because of such a feature, a nitride semiconductor light-emitting element has been expected to be applied to image display devices and lighting devices.

The nitride semiconductor has a wurtzite crystal structure. FIGS. 1(a), 1(b), and 1(c) respectively show the m-plane, the r-plane and the (11-2-2) plane of the wurtzite crystal structure with four characters (hexagonal indices). In a four-character expression, crystal planes and orientations are expressed using primitive vectors of a1, a2, a3, and c. The primitive vector c runs in the [0001] direction, which is called a “c-axis”. A plane that intersects with the c-axis at right angles is called either a “c-plane” or a “(0001) plane”.

FIG. 2(a) shows a molecular orbital model of the crystal structure of the nitride semiconductor. FIG. 2(b) shows an atomic arrangement at an m-plane surface, which is observed from the a-axis direction. FIG. 2(c) shows an atomic arrangement at a +c-plane surface, which is observed from the m-axis direction.

According to the conventional techniques, in fabricating a semiconductor element using nitride semiconductors, a c-plane substrate, i.e., a substrate which has a (0001)-plane principal surface, is used as a substrate on which nitride semiconductor crystals are to be grown. In this case, as seen from FIG. 2(c), a layer in which only Ga atoms are arranged along the c-axis direction and a layer in which only N atoms are arranged along the c-axis direction are formed. Due to such an arrangement of Ga atoms and N atoms, spontaneous electrical polarization is produced in the nitride semiconductor. That is why the “c-plane” is also called a “polar plane”.

As a result of the electrical polarization, a piezoelectric field is generated along the c-axis direction in the InGaN quantum well in the active layer of the nitride semiconductor light-emitting element and causes some positional deviation in the distributions of electrons and holes in the active layer, so that the internal quantum yield decreases due to the quantum confinement Stark effect of carriers.

Thus, it has been proposed that a substrate of which the principal surface is a so-called “non-polar plane”, such as m-plane or a-plane, or a so-called “semi-polar plane”, such as -r plane or (11-2-2) plane, be used. As shown in FIG. 1(a), the m-planes in the wurtzite crystal structure are parallel to the c-axis and are six equivalent planes which intersect with the c-plane at right angles. For example, in FIG. 1, the (1-100) plane that is perpendicular to the [1-100] direction is the m-plane. The other m-planes which are equivalent to the (1-100) plane include (-1010) plane, (10-10) plane, (-1100) plane, (01-10) plane, and (0-110) plane. Here, “-” attached on the left-hand side of a Miller-Bravais index in the parentheses means a “bar”, which conveniently represents inversion of that index.

FIG. 2(b) shows the positions of Ga and N of a nitride semiconductor crystal in a plane perpendicular to the m-plane. On the m-plane, as shown in FIG. 2(b), Ga atoms and N atoms are on the same atomic-plane. For that reason, no electrical polarization will be produced perpendicularly to the m-plane. Therefore, if a light-emitting element is fabricated using a semiconductor multilayer structure which has been formed on the m-plane, no piezoelectric field will be generated in the active layer, thus overcoming the problem of the decrease of the internal quantum yield which is attributed to the quantum confinement Stark effect of carriers.

Further, a nitride semiconductor light-emitting element which is formed on a so-called “non-polar plane”, such as m-plane or a-plane, or a so-called “semi-polar plane”, such as -r plane or (11-2-2) plane, has a polarization characteristic which is attributed to the structure of its valence band. For example, a nitride semiconductor active layer formed on the m-plane mainly emits light electric field intensity of which is deviated in a direction parallel to the a-axis. Such a polarization characteristic has been expected to be applied to, for example, a backlight for liquid crystal. As an idea for improving the polarization characteristic, for example, FIG. 4 of Patent Document 1 discloses a nitride semiconductor light-emitting element having an m-plane principal surface, in which a plane of two pairs of opposing planes perpendicular to the principal surface which is parallel to the c-plane is a longitudinal plane for the purpose of maintaining the polarization ratio of polarized light produced in an active layer.

On the other hand, it is theoretically estimated that, when the light-emitting element has a polarization characteristic, it has such a light distribution that the emission intensity is greater in a direction which is perpendicular to the polarization direction. Thus, Patent Document 2 proposes a light-emitting diode device which is capable of reducing the difference in intensity which is attributed to the difference in azimuth angle in a plane of the nitride semiconductor light-emitting element. Specifically, the fifth embodiment of Patent Document 2 discloses a configuration in which the light emission surface of a package is configured such that the direction of light is changed to a direction of an azimuth angle in which the emission intensity is small.

### CITATION LIST

### Patent Literature

Patent Document 1: Japanese Laid-Open Patent Publication No. 2009-43832

Patent Document 2: Japanese Laid-Open Patent Publication No. 2008-109098

### SUMMARY OF INVENTION

### Technical Problem

However, in the above-described conventional techniques, further improvement of the light distribution characteristics is a problem.

The present invention was conceived for the purpose of solving the above-described problem. One of the major objects of the present invention is to provide a semiconductor light-emitting device which has improved light distribution characteristics.

### Solution to Problem

A nitride semiconductor light-emitting element of one embodiment is a nitride semiconductor light-emitting element including a multilayer structure, the multilayer structure including an active layer made of an m-plane nitride semiconductor, wherein the multilayer structure has a first light extraction surface which is parallel to an en-plane in the active layer and a plurality of second light extraction surfaces which are parallel to a c-plane in the active layer, and a ratio of an area of the second light extraction surfaces to an area of the first light extraction surface is not more than 46%.

### Advantageous Effects of Invention

According to the present invention, the symmetry of the light distribution characteristics along the a-axis direction and the c-axis direction can be improved.

### BRIEF DESCRIPTION OF DRAWINGS

FIGS. 1(a) to 1(c) are diagrams showing a wurtzite crystal structure.

FIGS. 2(a) to 2(c) show the crystal structure of a nitride semiconductor using molecular orbital models.

FIGS. 3(a) to 3(c) show the configuration of a semiconductor light-emitting device of Embodiment 1.

FIGS. 4(a) to 4(c) are plan views showing light extraction surfaces 311a and 311b.

FIGS. 5(a) to 5(c3) are diagrams showing Variation 1 of the semiconductor light-emitting device of Embodiment 1.

FIGS. 6(a) to 6(d) are cross-sectional views for illustrating the process of dividing a wafer into chips for the nitride semiconductor light-emitting element 300 shown in FIG. 5(c-1).

FIGS. 7(a) to 7(c) are diagrams showing Variation 2 of Embodiment 1.

FIGS. 8(a) to 8(c) are diagrams showing Variation 3 of Embodiment 1.

FIGS. 9(a) to 9(c) are diagrams showing the configuration of a semiconductor light-emitting device of Embodiment 2.

FIGS. 10(a) to 10(c3) are diagrams showing Variation 1 of the semiconductor light-emitting device of Embodiment 2.

FIGS. 11(a) to 11(c) are diagrams showing the configuration of a semiconductor light-emitting device of Embodiment 3.

FIGS. 12(a) to 12(c3) are diagrams showing Variation 1 of Embodiment 3.

FIGS. 13(a) to 13(c) are diagrams showing the configuration of a semiconductor light-emitting device of still another embodiment.

FIGS. 14(a) to 14(c) are diagrams showing variations of the semiconductor light-emitting device of the still another embodiment.

FIGS. 15(a) and 15(b) are graphs showing the light distribution characteristics of a semiconductor light-emitting device of Inventive Example 1.

FIG. 16 is a graph showing the relationship between the ratio of the area of light extraction surfaces 311b to the area of a light extraction surface 311a and the asymmetry degree for Inventive Example 1.

FIGS. 17(a) and 17(b) are graphs showing the light distribution characteristics of a semiconductor light-emitting device of Inventive Example 2.

FIG. 18 is a graph showing the relationship between the ratio of the area of light extraction surfaces 311b to the area of a light extraction surface 311a and the asymmetry degree for Inventive Example 2.

FIGS. 19(a) and 19(b) are graphs showing the light distribution characteristics of a semiconductor light-emitting device of Inventive Example 3.

FIG. 20 is a graph showing the relationship between the ratio of the area of light extraction surfaces 311b to the area of a light extraction surface 311a and the asymmetry degree for Inventive Example 3.

FIGS. 21(a) and 21(b) are graphs showing the light distribution characteristics of a semiconductor light-emitting device of Inventive Example 4.

FIG. 22 is a graph showing the relationship between the ratio of the area of light extraction surfaces 311b to the area of a light extraction surface 311a and the asymmetry degree for Inventive Example 4.

FIGS. 23(a) to 23(c) are optical microscopic images of a nitride-based semiconductor light-emitting element which was separated by laser dicing.

FIGS. 24(a) to 24(c) are optical microscopic images of a nitride-based semiconductor light-emitting element which was separated by mechanical dicing.

FIGS. 25(a) to 25(c) are diagrams showing the configuration of a semiconductor light-emitting device of Comparative Example 1.

FIGS. 26(a) and 26(b) are graphs showing the light distribution characteristics of the semiconductor light-emitting device of Comparative Example 1.

FIGS. 27(a) to 27(c) are diagrams showing the configuration of a semiconductor light-emitting device of Comparative Example 2.

FIGS. 28(a) and 28(b) are graphs showing the light distribution characteristics of the semiconductor light-emitting device of Comparative Example 2.

FIGS. 29(a) and 29(b) are diagrams for illustrating a method for measuring the light distribution characteristics.

### DESCRIPTION OF EMBODIMENTS

A nitride semiconductor light-emitting element of the present embodiment is a nitride semiconductor light-emitting element which includes a multilayer structure, the multilayer structure including an active layer made of an m-plane nitride semiconductor, wherein the multilayer structure has a first light extraction surface which is parallel to an m-plane in the active layer and a plurality of second light extraction surfaces which are parallel to a c-plane in the active layer, and the ratio of an area of the second light extraction surfaces to an area of the first light extraction surface is not more than 46%.

With the above-described configuration, the symmetry of the light distribution characteristics along the a-axis direction and the c-axis direction can be improved.

The multilayer structure may have one or a plurality of third light extraction surfaces, and the one or plurality of third light extraction surfaces may be inclined with respect to a normal direction of the first light extraction surface.

The one or plurality of third light extraction surfaces may be inclined by 30° with respect to the normal direction of the first light extraction surface.

The multilayer structure may include a substrate which has a first surface and a second surface, the second surface being provided on an opposite side to the first surface, and a plurality of nitride-based semiconductor layers provided on the first surface of the substrate, the plurality of nitride-based semiconductor layers including the active layer.

The first light extraction surface may be the second surface of the substrate.

The multilayer structure may be constituted of a plurality of nitride-based semiconductor layers including the active layer.

A length along a c-axis direction of the first light extraction surface may be greater than a length along an a-axis direction of the first light extraction surface.

A ratio of an area of the second light extraction surface to an area of the first light extraction surface may be not less than 24%.

At least any of the first light extraction surface and the plurality of second light extraction surfaces may have a texture structure.

A semiconductor light-emitting device of one embodiment may include: the nitride semiconductor light-emitting element of the present embodiment; a mounting base which supports the nitride semiconductor light-emitting element; and a sealing portion covering the nitride semiconductor light-emitting element.

The semiconductor light-emitting device of one embodiment may further include a reflector for reflecting light emitted from the nitride semiconductor light-emitting element.

Embodiments of the present invention relate to a nitride semiconductor light-emitting element, such as a light-emitting diode and a laser diode, in the entire visible wavelength range ranging from ultraviolet to blue, green, orange and white, for example.

The present inventors carried out a semiconductor light-emitting device which includes a nitride semiconductor light-emitting element which has a nitride-based semiconductor multilayer structure having an m-plane principal surface in various forms and examined their characteristics in detail.

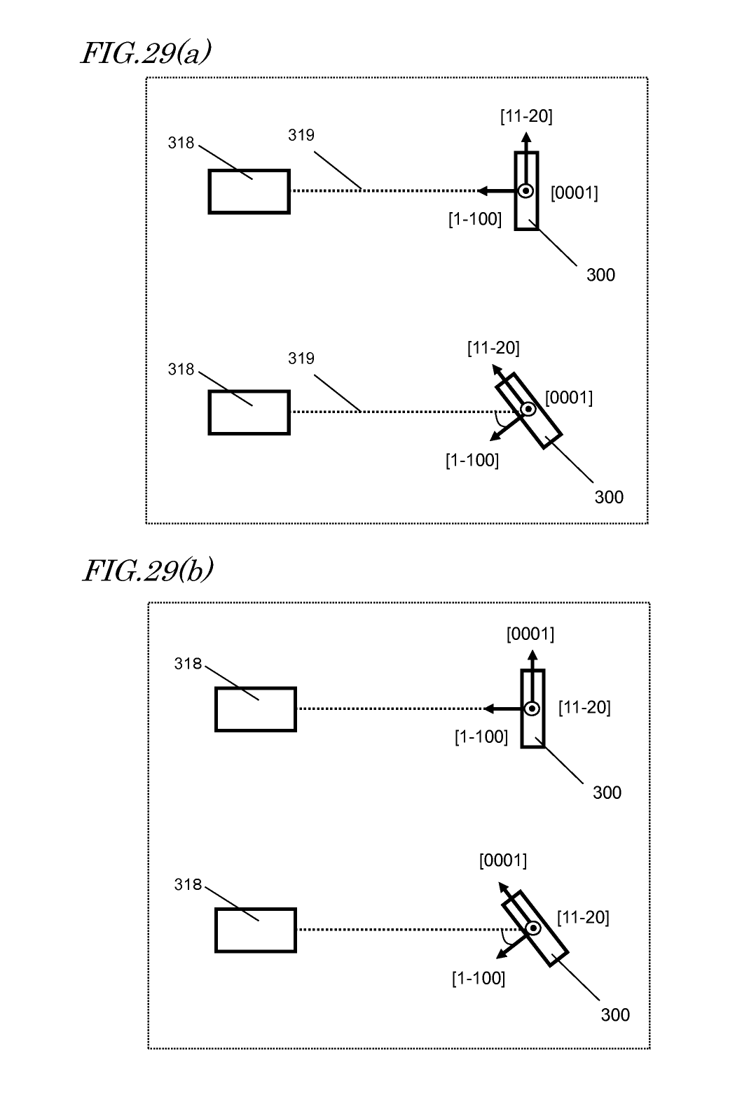

FIG. 29(a) is a diagram showing the positional relationship between a nitride semiconductor light-emitting element 300 and a light receiving section 318 for measurement of the light distribution characteristic along the a-axis direction. A line extending between the center of the nitride semiconductor light-emitting element 300 and the center of the light receiving section 318 is referred to as “measurement line 319”.

The light distribution characteristic along the a-axis direction refers to a value obtained by measuring the luminous intensity while rotating the nitride semiconductor light-emitting element 300 around the c-axis of the nitride semiconductor light-emitting element 300, with the angle formed between the normal direction [1-100] of the m-plane of the nitride semiconductor light-emitting element 300 and the measurement line 319 being the measurement angle. In FIG. 29(a), the upper part shows the positional relationship with the measurement angle being 0°, and the lower part shows the positional relationship with the measurement angle being 45°.

FIG. 29(b) is a diagram showing the positional relationship between the nitride semiconductor light-emitting element 300 and the light receiving section 318 for measurement of the light distribution characteristic along the c-axis direction.

The light distribution characteristic along the c-axis direction refers to a value obtained by measuring the luminous intensity while rotating the nitride semiconductor light-emitting element 300 around the a-axis of the nitride semiconductor light-emitting element 300, with the angle formed between the normal direction [1-100] of the m-plane of the nitride semiconductor light-emitting element 300 and the measurement line 319 being the measurement angle. In FIG. 29(b), the upper part shows the positional relationship with the measurement angle being 0°, and the lower part shows the positional relationship with the measurement angle being 45°.

In this specification, the asymmetry degree of the light distribution characteristics along the a-axis direction and the c-axis direction refers to a value which is obtained by normalizing the difference between a luminous intensity in a direction which is rotated in the a-axis direction by a predetermined angle from the normal direction [1-100] of the m-plane that is the principal surface (i.e., 0°) and a luminous intensity in a direction which is rotated in the c-axis direction by an equal angle from the normal direction of the m-plane, with the luminous intensity in the normal direction of the m-plane. This asymmetry degree is defined for respective angles in the range of −90° to +90°. The maximum asymmetry degree refers to the maximum value of the asymmetry degree in the range of −90° to +90°. The average asymmetry degree refers to the average value of the asymmetry degree in the range of −90° to +90°.

As a result of this measurement, the present inventors discovered that the light distribution characteristic along the a-axis direction and the light distribution characteristic along the c-axis direction strongly depend on the area ratio of a light extraction surface which is the m-plane to a light extraction surface which is the c-plane. Based on this discovery, the present inventors conceived a method for improving the asymmetry of the light distribution characteristics along the a-axis direction and the c-axis direction.

Hereinafter, embodiments of the present invention will be described with reference to the drawings. In the drawings mentioned below, for the sake of simple description, elements which perform substantially the same functions are denoted by the same reference numerals. Note that the present invention is not limited to the embodiments which will be described below.

### Embodiment 1

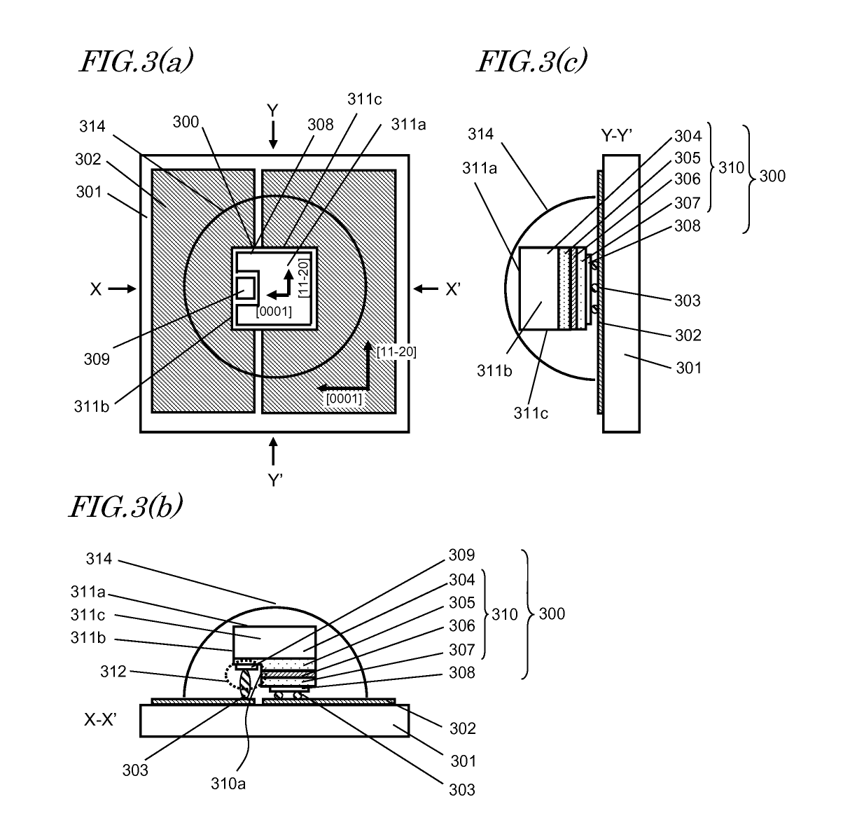

Hereinafter, Embodiment 1 of a light-emitting device of the present invention is described with reference to FIG. 3.

FIG. 3 schematically shows a semiconductor device of Embodiment 1. FIG. 3(a) is a top view. FIG. 3(b) is a cross-sectional view taken along line X-X′. FIG. 3(c) is a cross-sectional view taken along line Y-Y′.

The light-emitting device of the present embodiment includes the nitride semiconductor light-emitting element 300. The nitride semiconductor light-emitting element 300 is electrically coupled to a wire 302 which is provided on a mounting base 301 via a bump 303.

The nitride semiconductor light-emitting element 300 of the present embodiment has a multilayer structure 310 which includes a nitride semiconductor active layer 306 made of an m-plane nitride semiconductor. The multilayer structure 310 has a light extraction surface 311a which is parallel to the m-plane in the nitride semiconductor active layer 306 and light extraction surfaces 311b which are parallel to the c-plane in the nitride semiconductor active layer 306. The ratio of the area of the second light extraction surfaces 311b to the area of the light extraction surface 311a is not more than 46%.

The m-plane nitride semiconductor refers to a nitride semiconductor in which the m-plane is the growing surface or the principal surface. The nitride semiconductor active layer 306 is provided on the m-plane. The nitride semiconductor active layer formed on the m-plane mainly emits light electric field intensity of which is deviated in a direction parallel to the a-axis. Therefore, in the m-plane nitride semiconductor light-emitting element 300, the emission intensity is greater in a direction perpendicular to the polarization direction (a-axis direction), i.e., in the c-axis direction. If the light extraction surfaces 311a and 311b have equal areas, the intensity of light would have unevenness. According to the present embodiment, the ratio of the area of the second light extraction surfaces 311b to the area of the light extraction surface 311a is not more than 46%, so that the ratio of the amount of light emitted from the second light extraction surfaces 311b to the amount of light emitted from the first light extraction surface 311a can be reduced. Thus, the emission intensity in the c-axis direction can be reduced. In this way, the symmetry of the light distribution characteristics along the a-axis direction and the c-axis direction can be improved. The reasons for this result will be described later.

The multilayer structure 310 includes, specifically, a substrate 304 which includes an m-plane GaN layer, an n-type nitride semiconductor layer 305 which is formed on the m-plane GaN layer, a nitride semiconductor active layer 306, and a p-type nitride semiconductor layer 307.

There is a p-side electrode 308 which is in contact with the p-type nitride semiconductor layer 307 in the multilayer structure 310. Part of the multilayer structure 310 is provided with a recessed portion 312 penetrating through the p-type nitride semiconductor layer 307 and the nitride semiconductor active layer 306. Through the recessed portion 312, the n-type nitride semiconductor layer 305 is exposed at the bottom surface. There is a n-side electrode 309 which is in contact with the n-type nitride semiconductor layer 305 at the bottom surface of the recessed portion 312. The multilayer structure 310, the p-side electrode 308, and the n-side electrode 309 constitute the nitride semiconductor light-emitting element 300.

The nitride semiconductor may be, for example, a GaN-based semiconductor and may also be an AlₓIn_{y}Ga_{z}N (x+y+z=1, x≧0, y≧0, z≧0) semiconductor.

In the present invention, the “m-plane”, the “c-plane”, and the “a-plane” include not only a plane which is perfectly parallel to the m-plane, the c-plane, or the a-plane but also a plane which is inclined by an angle absolute value of which is not more than 5° with respect to the en-plane, the c-plane, or the a-plane.

With just a slight incline with respect to the en-plane, the c-plane, or the a-plane, the effect of the spontaneous electrical polarization is very small. On the other hand, according to the crystal growth technology, epitaxial growth of a semiconductor layer is easier on a substrate in which the crystal orientation is slightly inclined rather than on a substrate in which the crystal orientation is strictly identical. Thus, in some cases, it may be preferred to incline the crystal plane for the purpose of improving the quality of a semiconductor layer which is to be epitaxially grown or increasing the crystal growth rate, while sufficiently decreasing the effect of the spontaneous electrical polarization.

The substrate 304 may be an m-plane GaN substrate or may be a substrate which is obtained by forming an m-plane GaN layer on a heterogeneous substrate (for example, a substrate which is obtained by forming an m-plane GaN layer on an m-plane SiC substrate or a substrate which is obtained by forming an m-plane GaN layer on an r-plane sapphire substrate). The surface of the substrate 304 is not limited to the m-plane. The plane orientation (for example, a non-polar plane, such as a-plane, or a semi-polar plane, such as r-plane and {11-22} plane) may be selected such that light emitted from the active layer has a polarization characteristic. An undoped GaN layer may be provided between the nitride semiconductor active layer 306 and the p-type nitride semiconductor layer 307.

The n-type nitride semiconductor layer 305 is made of, for example, n-type AlᵤGaᵥIn_{w}N (u+v+w=1, u≧0, v≧0, w≧0). The n-type dopant used may be, for example, silicon (Si).

The p-type nitride semiconductor layer 307 is made of, for example, a p-type Al₈GaₜN (s+t=1, s≧0, t≧0) semiconductor. As the p-type dopant, for example, Mg is added. Examples of the p-type dopant other than Mg include Zn and Be. In the p-type nitride semiconductor layer 307, the mole fraction of Al, s, may be uniform along the thickness direction. Alternatively, the Al mole fraction s may vary either continuously or stepwise along the thickness direction. Specifically, the thickness of the p-type nitride semiconductor layer 307 is, for example, approximately not less than 0.05 μm and not more than 2 μm.

Part of the p-type nitride semiconductor layer 307 near the upper surface, i.e., near the interface with the p-side electrode 308, may be made of a semiconductor Al mole fraction s of which is zero, i.e., GaN. Also, in this case, the GaN may contain a p-type impurity with high concentration and may function as a contact layer.

The nitride semiconductor active layer 306 has a GaInN/GaInN multi-quantum well (MQW) structure in which, for example, Ga₁₋ₓInₓN well layers, each having a thickness of about 3 to 20 nm, and Ga_{1-y}In_{y}N well layers (0≦y<x<1) barrier layers, each having a thickness of about 5 to 30 nm, are alternately stacked one upon the other. The wavelength of light emitted from the nitride semiconductor light-emitting element 300 depends on the mole fraction of In, x, in the Ga₁₋ₓInₓN semiconductor that is the semiconductor composition of the above-described well layers. A piezoelectric field would not be generated in the nitride semiconductor active layer 306 formed on the m-plane. Therefore, decrease of the luminous efficacy can be prevented even when the In mole fraction is increased.

The n-side electrode 309 has, for example, a multilayer structure of a Ti layer and a Pt layer (Ti/Pt). Further, Al may be used for the n-side electrode 309 in order to increase the reflectance. The p-side electrode 308 may generally cover the entire principal surface of the p-type nitride semiconductor layer 307. The p-side electrode 308 has, for example, a multilayer structure of a Pd layer and a Pt layer (Pd/Pt). Further, Ag may be used for the p-side electrode 308 in order to increase the reflectance.

The nitride semiconductor light-emitting element 300 is provided on the mounting base 301 on which the wire 302 has been formed, with the p-side electrode 308 side down. The base material of the mounting base 301 may be an insulating material such as alumina or AIN, a metal such as Al or Cu, a semiconductor such as Si or Ge, or a composite material thereof. When a metal or semiconductor is used as the base material of the mounting base 301, the surface may be covered with an insulating film. The wire 302 may be arranged according to the electrode shape of the nitride semiconductor light-emitting element 300. For the wire 302, Cu, Au, Ag or Al may be used. The nitride semiconductor light-emitting element 300 and the wire 302 are electrically coupled together using the bump 303. Au is preferably used for the bump. Here, a flip-chip structure has been described, but the present invention is not limited to this structure. The mounting base 301 and the wire 302 may be coupled together by means of wire bonding.

The nitride semiconductor light-emitting element 300 is covered with a sealing portion 314 such that the nitride semiconductor light-emitting element 300 is enclosed by the sealing portion 314. The material used for the sealing portion 314 may be an epoxy resin, a silicone resin or glass. The refractive index of the sealing portion 314 is set to approximately not less than 1.4 and not more than 2.0, whereby the amount of light extracted from the nitride semiconductor light-emitting element 300 to the sealing portion 314 can be increased. The surface shape of the sealing portion 314 may be a hemispherical shape. When the sealing portion 314 has a hemispherical surface shape, light extracted from the nitride semiconductor light-emitting element 300 to the sealing portion 314 is less likely to undergo total reflection at the interface between the sealing portion 314 and the air, and as a result, the amount of light extracted to the outside increases.

The multilayer structure 310 has light extraction surfaces 311a, 311b, and 311c through which light emitted from the nitride semiconductor active layer 306 can be extracted to the outside. The light extraction surface 311a is a surface which is generally parallel to the layer direction of the multilayer structure 310 and is provided so as to face the p-side electrode 308 and the n-side electrode 309. That is, the light extraction surface 311a is generally parallel to the m-plane of the nitride semiconductor active layer 306. The light extraction surfaces 311b include two surfaces which face each other and are generally parallel to the c-plane of the nitride semiconductor active layer 306.

The light extraction surface 311c is constituted of two surfaces which face each other, and the plane orientation of its principal surface is not limited to a particular direction. In FIG. 3, the light extraction surface 311c is (11-20) plane. The multilayer structure 310 may include still another light extraction surface in addition to the above-described five light extraction surfaces. Further, the entirety or some portions of the above-described five light extraction surfaces may have a texture structure. In the present embodiment, the normal line or inclination of a light extraction surface in a case where the texture structure is provided refers to the normal line or inclination of the light extraction surface before formation of the texture structure. The case where the texture structure is provided will be described later.

Since the multilayer structure 310 is transparent in the visible range, the shapes of the p-side electrode 308 and the n-side electrode 309 emerge at the light extraction surface 311a and other surfaces which face the electrodes in FIG. 3 and other drawings.

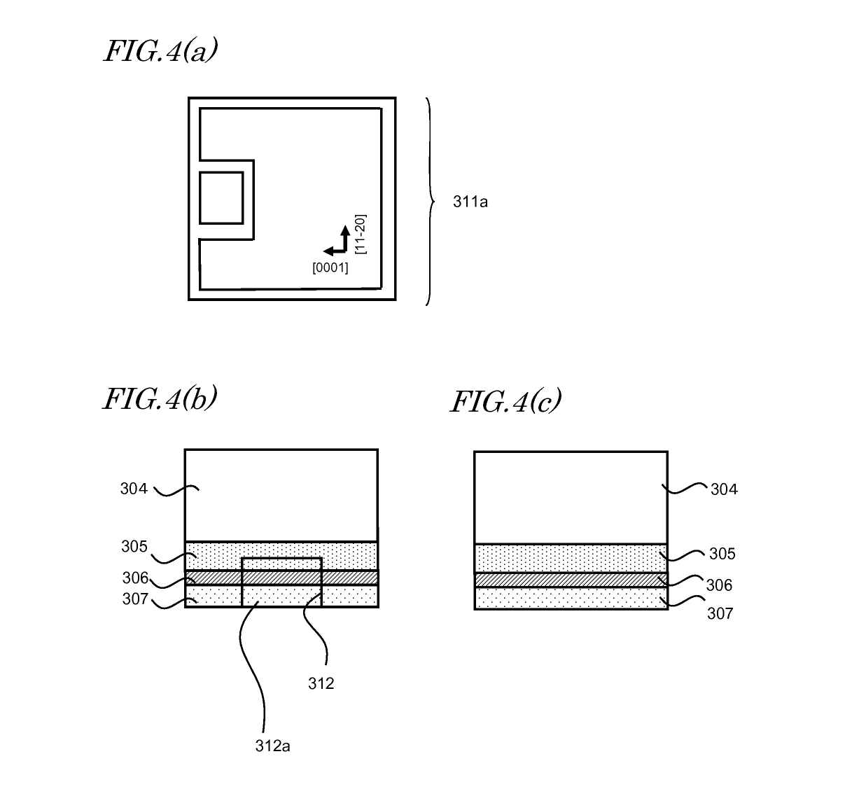

FIGS. 4(a) to 4(c) are plan views showing the light extraction surfaces 311a and 311b. As shown in FIG. 4(a), in the present embodiment, the light extraction surface 311a has a square shape.

The light extraction surfaces 311b include two surfaces which face each other. FIG. 4(b) shows one of the light extraction surfaces 311b in which the recessed portion 312 is provided for providing the n-side electrode 309. The inside of the recessed portion 312 has a lateral surface 312a of the recessed portion 312. In the lateral surface 312a, the n-type nitride semiconductor layer 305, the nitride semiconductor active layer 306, and the p-type nitride semiconductor layer 307 are partially exposed. The lateral surfaces of the recessed portion 312 include a surface which is parallel to the c-plane. However, this surface that is parallel to the c-plane is very small, and extraction of light from this surface is obstructed by the n-side electrode 309 and the bump 303 that couples the n-side electrode 309 and the wire 302. Therefore, this surface can be omitted from the light extraction surfaces.

FIG. 4(c) shows one of the light extraction surfaces 311b which is provided opposite to the side on which the recessed portion 312 is provided.

The substrate 304 is ground so as to be a thin film, whereby the light extraction surface 311a is formed. The substrate 304 can be converted to a thin film having a thickness of about 20 μm. If the thickness of the substrate 304 is less than 20 μm, cracks are readily formed in the mounting step.

As a result of grinding, the light extraction surface 311a may not be perfectly identical with the m-plane in some cases. Therefore, the light extraction surface 311a may be a surface which is inclined by an angle of not more than 10° with respect to the m-plane.

Thus, in the present embodiment, “a light extraction surface which is parallel to the m-plane” may include a light extraction surface which is inclined by an angle of not more than 10° with respect to the m-plane.

When a treatment, such as grinding, is performed on the surface of the light extraction surface 311a, it is difficult to make the light extraction surface 311a perfectly smooth. Therefore, the light extraction surface 311a may have an arithmetic mean roughness (Ra) of approximately not less than 0 and not more than 100 nm.

The nitride semiconductor light-emitting element 300 that is in the form of a chip can be formed by cleaving a wafer or splitting a wafer by laser dicing. As a result of cleaving or laser dicing, the light extraction surfaces 311b may not be perfectly identical with the c-plane in some cases. Therefore, the light extraction surfaces 311b may be surfaces which are inclined by an angle of not more than 10° with respect to the c-plane.

Thus, in the present embodiment, “a light extraction surface which is parallel to the c-plane” may include a light extraction surface which is inclined by an angle of not more than 10° with respect to the c-plane.

When considered microscopically, the light extraction surfaces 311b may be constituted of a plurality of surfaces, each of which is inclined by an angle of not less than 0° and not more than 30° with respect to the c-plane.

As a result of cleaving or laser dicing, the light extraction surface 311c may not be perfectly identical with the a-plane in some cases, as in the case of the light extraction surfaces 311b. Therefore, the light extraction surface 311c may be a surface which is inclined by an angle of not more than 10° with respect to the a-plane. When considered microscopically, the light extraction surface 311c may be constituted of a plurality of surfaces, each of which is inclined by an angle of not less than 0° and not more than 30° with respect to the a-plane.

The nitride semiconductor active layer 306 formed on the m-plane emits light electric field intensity of which is deviated in a direction parallel to the a-axis. Such a deviation of the electric field intensity depends on the behaviors of the upper two of the valence bands (A band and B band). Since light has such a characteristic that it travels in a direction perpendicular to an electric field, light emitted from the nitride semiconductor active layer 306 travels with a deviation in a direction perpendicular to the a-axis, propagates in such a manner that it repeatedly undergoes reflection inside the nitride semiconductor light-emitting element 300, and is then extracted to the outside from the light extraction surfaces 311a, 311b, and 311c. However, since light emitted from the nitride semiconductor active layer 306 travels with a deviation in a direction perpendicular to the a-axis, the surfaces which largely contribute to light emission to the outside are the light extraction surfaces 311a and 311b that are generally parallel to the a-axis. Light emission to the outside from the light extraction surface 311c that is generally perpendicular to the a-axis is small as compared with those from the light extraction surfaces 311a and 311b.

Since the amount of light emitted from the light extraction surface 311c is small, the light distribution characteristic of light emitted from the light extraction surface 311a is strongly reflected in the light distribution characteristic along the a-axis direction. The light distribution characteristic along the a-axis direction is such that the luminous intensity is the strongest when the measurement angle is around 0°, and the luminous intensity monotonically decreases as the measurement angle increases.

On the other hand, the light distribution characteristics of light extracted from the light extraction surfaces 311a and 311b are strongly reflected in the light distribution characteristic along the c-axis direction.

Thus, the difference in the amount of light emitted from the light extraction surfaces 311a, 311b, and 311c produces asymmetry in the light distribution characteristic along the a-axis direction and the light distribution characteristic along the c-axis direction.

To control the amount of light emission from the light extraction surfaces 311a and 311b, in the present embodiment, the area of the light extraction surfaces 311b (the total area of two opposite surfaces) is not more than 46% of the area of the light extraction surface 311a.

By configuring the light extraction surfaces 311a and 311b having the above area ratio, the light distribution characteristic along the c-axis direction is such that the luminous intensity is the strongest around 0° and monotonically decreases as the angle increases where the normal direction [1-100] of the m-plane is assumed as 0°. Further, the average asymmetry degree of the light distribution along the a-axis direction and the light distribution along the c-axis direction can be not more than 12%.

When the size of the nitride semiconductor light-emitting element 300 is determined, the area of the light extraction surface 311a is almost necessarily determined. In that case, the area of the light extraction surfaces 311b can be controlled according to the thickness of the substrate 304.

As the ratio of the area of the light extraction surfaces 311b to the area of the light extraction surface 311a decreases, the asymmetry settles at an approximately constant value, and substantially no improvement is achieved beyond that value. This is because the light distribution characteristics of light emitted from the light extraction surface 311a cannot be improved. To decrease the area of the light extraction surfaces 311b, it is necessary to decrease the thickness of the substrate 304. If the value of the above ratio is not less than 24%, only a small amount of grinding of the substrate 304 is required, and the asymmetry of light can be sufficiently reduced. Thus, manufacture can be easy.

However, the ratio of the area of the light extraction surfaces 311b to the area of the light extraction surface 311a may be less than 24%. For example, when the substrate 304 is completely removed (Variation 3 of Embodiment 1), the value of the above ratio may be not less than 1%.

Next, a manufacturing method of the present embodiment, i.e., Embodiment 1, is described with reference to FIG. 3.

On a substrate 304 which includes n-type GaN having an m-plane principal surface, an n-type nitride semiconductor layer 305 is epitaxially grown using an MOCVD method. For example, an n-type nitride semiconductor layer 305 made of GaN and having a thickness of about 1 to 3 μm is formed at a growth temperature of not less than 900° C. and not more than 1100° C., using silicon as the n-type impurity, while supplying TMG (Ga(CH₃)₃) and NH₃ as the source materials.

Then, a nitride semiconductor active layer 306 is formed on the n-type nitride semiconductor layer 305. The nitride semiconductor active layer 306 has a GaInN/GaN multi-quantum well (MQW) structure in which, for example, 15 nm thick Ga₁₋ₓInₓN well layers and 30 nm thick GaN barrier layers are alternately stacked. In forming the Ga₁₋ₓInₓN well layers, the growth temperature is decreased to 800° C. so that In can be desirably taken in. The emission wavelength is selected according to the use for the nitride semiconductor light-emitting element 300, and the In mole fraction x is determined according to the wavelength. When the wavelength is 450 nm (blue), the In mole fraction x is determined as 0.18 to 0.2. When the wavelength is 520 nm (green), x=0.29 to 0.31. When the wavelength is 630 nm (red), x=0.43 to 0.44.

A p-type nitride semiconductor layer 307 is formed on the nitride semiconductor active layer 306. For example, a p-type nitride semiconductor layer 307 which has a thickness of about 50 to 500 nm and which is made of p-type GaN is formed at a growth temperature of not less than 900° C. and not more than 1100° C., using Cp₂Mg (cyclopentadienyl magnesium) as the p-type impurity, while supplying TMG and NH₃ as the source materials. Inside the p-type nitride semiconductor layer 307, a p-AlGaN layer which has a thickness of about 15 to 30 nm may be included. Providing the p-AlGaN layer enables prevention of an overflow of electrons in operation.

Then, for the purpose of activating a p-GaN layer, a heat treatment is performed at a temperature of about 800 to 900° C. for about 20 minutes.

Then, dry etching is performed using a chlorine gas such that the p-type nitride semiconductor layer 307, the nitride semiconductor active layer 306, and the n-type nitride semiconductor layer 305 are partially removed to form a recessed portion 312, whereby part of the n-type nitride semiconductor layer 305 is exposed.

Here, by controlling the conditions for the dry etching, angles formed between a portion of the n-type nitride semiconductor layer 305 and lateral surfaces of the nitride semiconductor active layer 306 and the p-type nitride semiconductor layer 307 and the light extraction surface 311a can be controlled. For example, when such conditions that provide a high physical etching property are employed where the etching pressure is decreased and the ion extraction voltage is increased, a lateral surface which is generally perpendicular to the light extraction surface 311a can be formed. On the other hand, when such conditions that provide a high chemical etching property are employed where an ICP plasma source of high plasma density is used and the ion extraction voltage is low, a lateral surface which is inclined with respect to the normal direction of the light extraction surface 311a can be formed.

Then, a n-side electrode 309 is formed so as to be in contact with the exposed part of the n-type nitride semiconductor layer 305. For example, Ti/Pt layers are formed as the n-side electrode 309. Further, a p-side electrode 308 is formed so as to be in contact with the p-type nitride semiconductor layer 307. For example, Pd/Pt layers are formed as the p-side electrode 308. Thereafter, a heat treatment is performed such that the Ti/Pt layers and the n-type nitride semiconductor layer 305 are alloyed together, and the Pd/Pt layers and the p-type nitride semiconductor layer 307 are also alloyed together.

Thereafter, the substrate 304 is ground so as to be a thin film. In the thin film, the area of the light extraction surfaces 311b (the total area of two opposite surfaces) is not more than 44% of the area of the light extraction surface 311a.

The thus-manufactured nitride semiconductor light-emitting element 300 that has been in the form of a wafer is separated by laser dicing, for example, so as to have a predetermined size. In the laser dicing, grooves are formed using a laser in the substrate 304 along the c-axis direction and the a-axis direction [11-20] such that the grooves have a depth of about several tens of micrometers from the surface, and then, breaking is performed such that it is separated into small chips of a predetermined size. In this step, the c-plane is likely to emerge over the light extraction surfaces 311b, and the a-plane is likely to emerge over the light extraction surface 311c. If the thickness of the substrate 304 is not more than 100 μm, it can be perfectly separated into small chips using a laser, and the breaking is not necessary.

The nitride semiconductor light-emitting element 300 that is separated into a small chip as described above is mounted on the mounting base 301. Here, a flip-chip structure is described.

On the mounting base 301, the wire 302 is formed in advance. As the base material of the mounting base, an insulating material such as alumina or AIN, a metal such as Al or Cu, a semiconductor such as Si or Ge, or a composite material thereof may be used. When the metal or semiconductor is used as the base material of the mounting base 301, the surface of the mounting base 301 may be covered with an insulating film. The wire 302 may be arranged according to the electrode shape of the nitride semiconductor light-emitting element 300. For the wire 302, Cu, Au, Ag or Al may be used. The wire 302 may be arranged according to the electrode shape of the nitride semiconductor light-emitting element 300. For the wire 302, Cu, Au, Ag or Al may be used. These materials may be provided on the mounting base 301 by sputtering or plating.

A bump 303 is formed on the wire 302. Au is preferably used for the bump 303. In forming the Au bump, a Au bump having a diameter of about 50 to 70 μm may be formed using a bump bonder. Alternatively, the Au bump may also be formed by Au plating. To the mounting base 301 on which the bump 303 has been formed in this way, the nitride semiconductor light-emitting element 300 is coupled by ultrasonic bonding.

Then, a sealing portion 314 is formed. For the sealing portion 314, an epoxy resin or a silicone resin may be used. As for the shape of the sealing portion 314, a mold is placed over the mounting base 301 on which the nitride semiconductor light-emitting element 300 has been mounted, and a resin is injected into the space between the mold and the mounting base 301. According to this method, the shaping of the sealing portion 314 and the resin encapsulation of the nitride semiconductor light-emitting element 300 can be performed concurrently. According to a possible alternative method, a sealing portion 314 having a space left for the nitride semiconductor light-emitting element 300 is prepared in advance. The thus-prepared transparent sealing portion 320 is placed over the mounting base 301 on which the nitride semiconductor light-emitting element 300 has been mounted, and then, a resin is injected into the space.

In this way, the semiconductor light-emitting device of the present embodiment is completed.

### Variation 1 of Embodiment 1

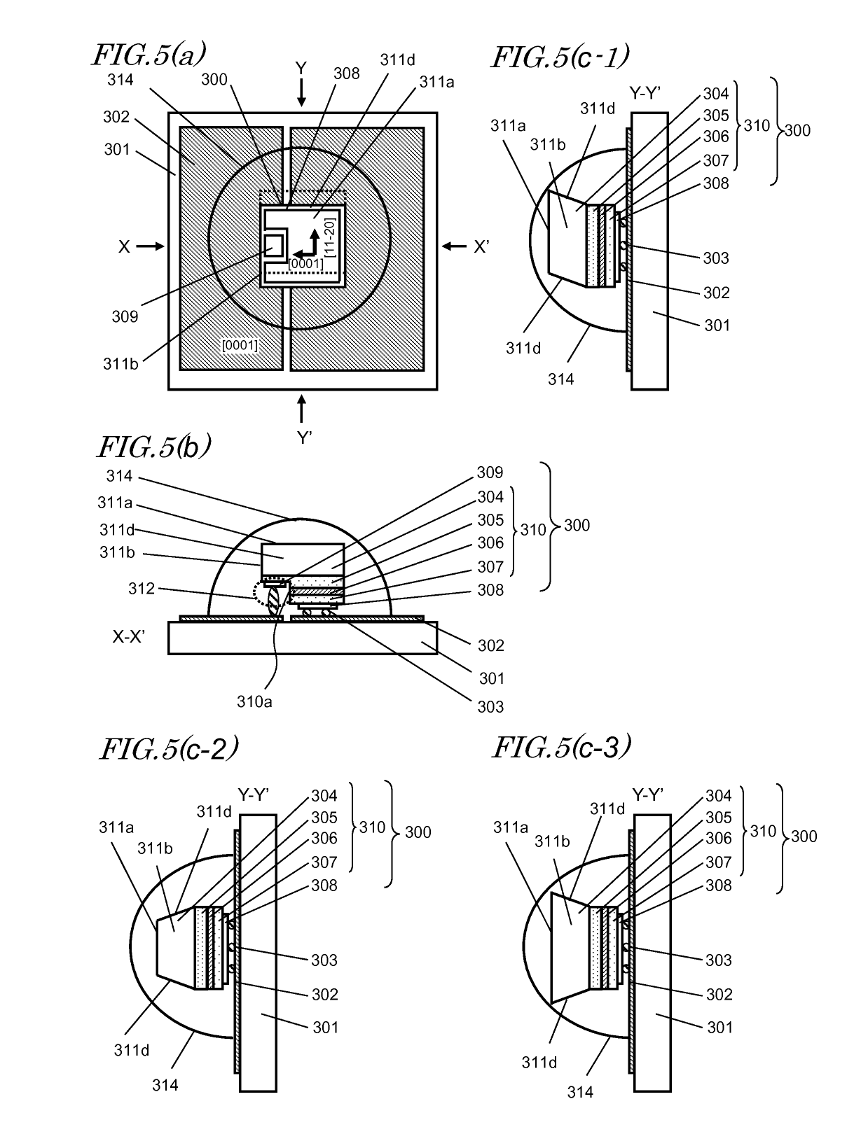

FIG. 5 shows Variation 1 of Embodiment 1. In the description provided below, the features of Embodiment 1 which have already been described above will not be described again.

In Variation 1, the multilayer structure 310 has light extraction surfaces 311a, 311b, and 311d. The light extraction surface 311a is formed generally parallel to the layer direction of the nitride-based semiconductor multilayer structure and formed so as to face the p-side electrode 308 and the n-side electrode 309. Therefore, the light extraction surface 311a is generally parallel to the m-plane. The light extraction surfaces 311b include two opposite surfaces and are generally parallel to the c-plane of the nitride semiconductor active layer 306.

The light extraction surfaces 311d include four lateral surfaces and are formed by the substrate 304, the n-type nitride semiconductor layer 305, the nitride semiconductor active layer 306, and the p-type nitride semiconductor layer 307. Of the light extraction surfaces 311d, one or both of two lateral surfaces of the substrate 304 are inclined with respect to the normal direction of the light extraction surface 311a. This incline is, for example, 30°. The surfaces are generally parallel to an m-plane which is different from the m-plane on which the nitride semiconductor active layer 306 has been formed.

A portion of the light extraction surfaces 311d which is formed by the n-type nitride semiconductor layer 305, the nitride semiconductor active layer 306, and the p-type nitride semiconductor layer 307 is parallel to the a-plane ((11-20) plane).

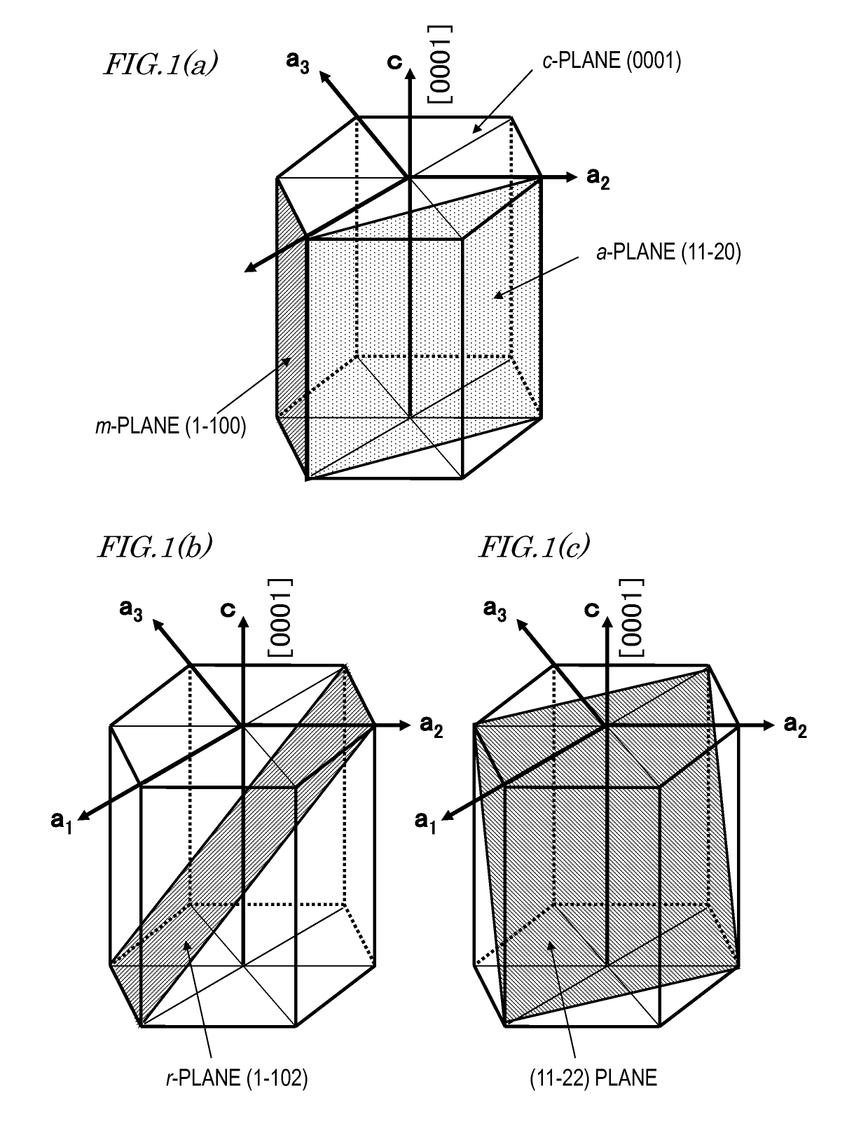

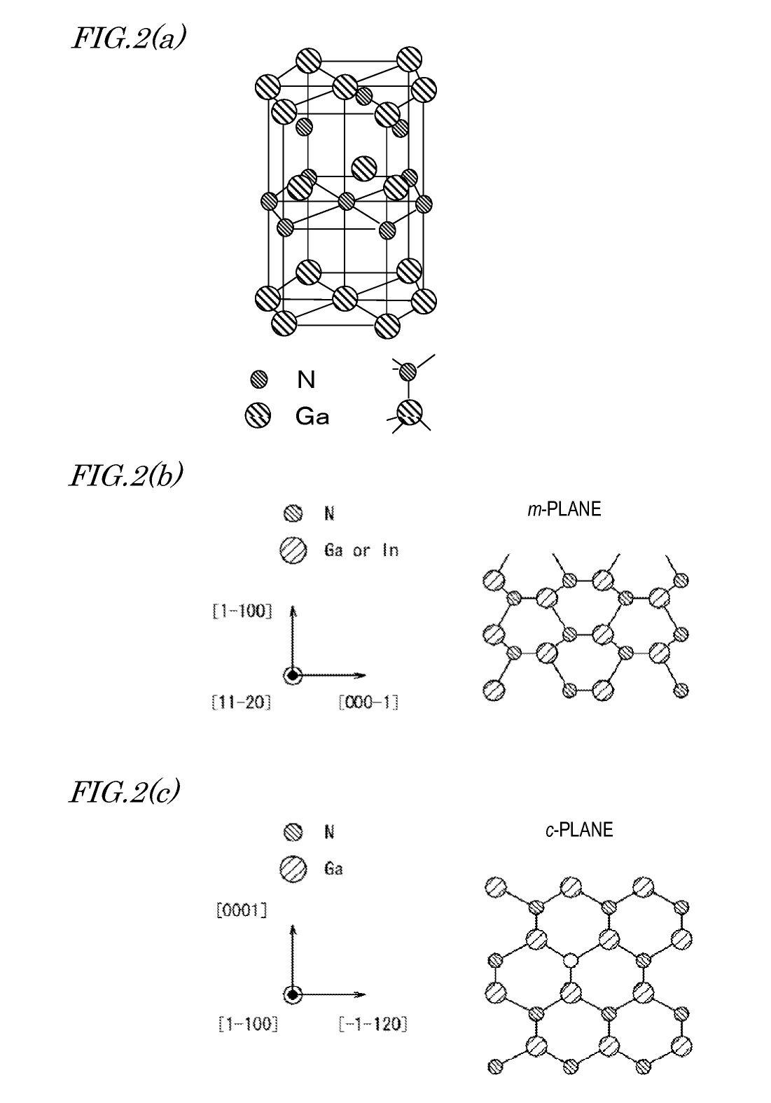

As shown in FIG. 5(c-1), two of the light extraction surfaces 311d may be inclined in the same direction with respect to the normal direction of the light extraction surface 311a, while the other two light extraction surfaces 311d may be arranged parallel to each other. As shown in FIGS. 5(c-2) and 5(c-3), two of the light extraction surfaces 311d may be inclined in different directions with respect to the normal direction of the light extraction surface 311a. In FIG. 5(c-2), the light extraction surface 311d in the substrate 304 is inclined such that the width along the a-axis direction ([11-20] direction) becomes narrower with the increase of the distance from the n-type nitride semiconductor layer 305. In FIG. 5(c-3), the light extraction surface 311d in the substrate 304 is inclined such that the width along the a-axis direction ([11-20] direction) becomes wider with the increase of the distance from the n-type nitride semiconductor layer 305.

According to this variation, the light extraction surfaces 311d are inclined with respect to the normal direction of the light extraction surface 311a, and therefore, light reflected inside the nitride semiconductor light-emitting element 300 is more likely to be extracted to the outside, so that the optical output improves. When the light extraction surface 311a and the light extraction surface 311c intersect with each other at approximately right angles as shown in FIG. 3(c) of Embodiment 1, light which is incident on the light extraction surface 311a or the light extraction surface 311c at an angle which is not less than the critical angle is confined inside the nitride semiconductor light-emitting element 300, without being extracted to the outside. On the other hand, when one or a plurality of the light extraction surfaces 311d are inclined as in this variation, light which is incident on the light extraction surface 311a at an angle which is not less than the critical angle undergoes total reflection at the light extraction surface 311a. On the other hand, on the light extraction surfaces 311d, light is likely to be incident at an angle which is not more than the critical angle, and therefore, increase is the amount of light which is extracted from the inside of the nitride semiconductor light-emitting element 300 to the outside. Thus, a semiconductor light-emitting device which is capable of a large optical output can be realized. One or a plurality of the light extraction surfaces 311d may be inclined by 30° with respect to the normal direction of the light extraction surface 311a. This configuration further increases the amount of light which is extracted from the inside of the nitride semiconductor light-emitting element 300 to the outside.

When it is attempted to form one or a plurality of the light extraction surfaces 311d by cleaving or laser dicing so as to be inclined by 30° with respect to the normal direction of the light extraction surface 311a, the angle of the incline may vary in some cases. Therefore, one or a plurality of the light extraction surfaces 311d may be surfaces which are inclined by an angle which is not less than 20° and not more than 40° with respect to the normal direction of the light extraction surface 311a.

Thus, in the present invention, “a light extraction surface which is inclined by 30° with respect to the normal direction of the first light extraction surface” may include a light extraction surface which is inclined by an angle absolute value of which is not less than 20° and not more than 40° with respect to the normal direction of the first light extraction surface.

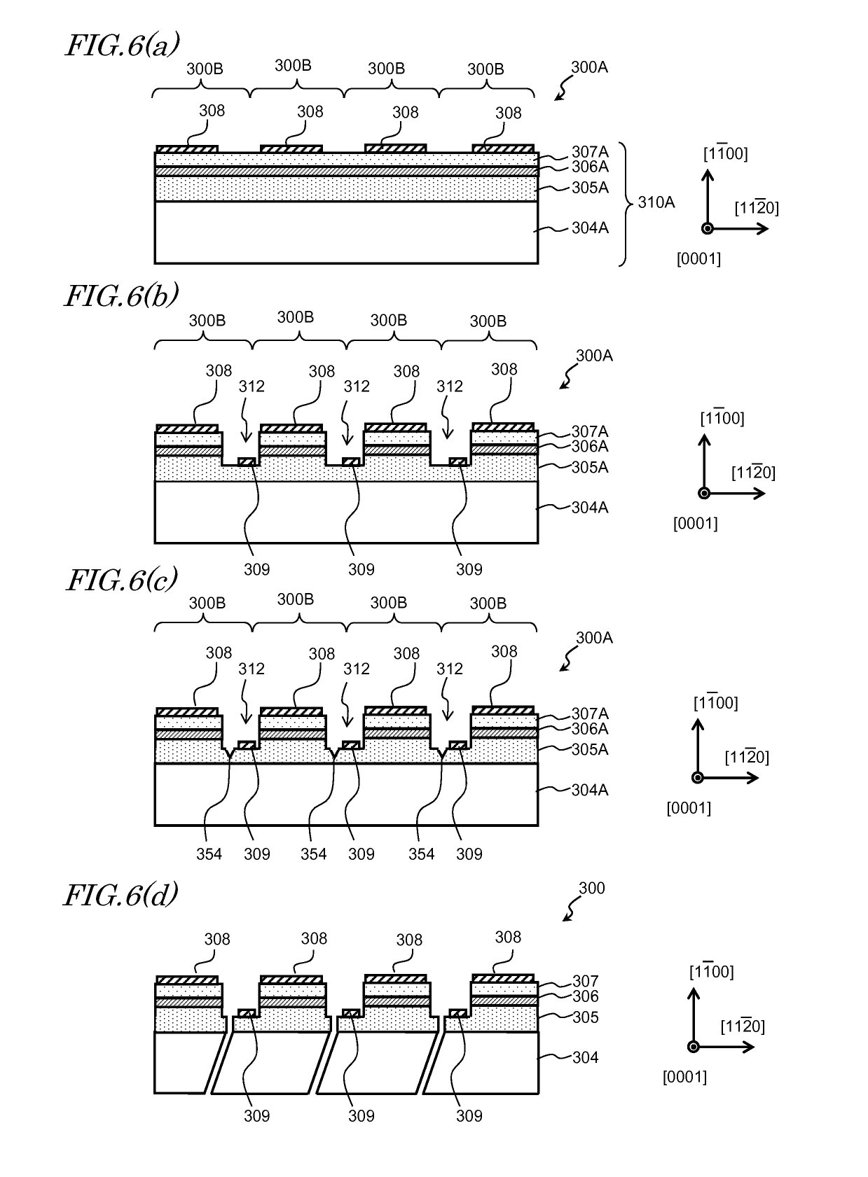

FIG. 6 shows cross-sectional views for illustrating the process of separating the nitride semiconductor light-emitting element 300 shown in FIG. 5(c-1), from a wafer into chips. FIG. 6 shows a cross-sectional view which is perpendicular to the c-axis direction ([0001] direction).

First, a wafer 300A such as shown in FIG. 6(a) is provided. The wafer 300A has a multilayer structure 310A. The multilayer structure 310A includes a substrate 304A, an n-type nitride semiconductor layer 305A, a nitride semiconductor active layer 306A, and a p-type nitride semiconductor layer 307A. On the p-type nitride semiconductor layer 307A, p-side electrodes 308 are provided. Note that the p-side electrodes 308 are provided in respective chip regions 300B (which will constitute chips after a subsequent separation step) according to a lift-off method.

Then, as shown in FIG. 6(b), recessed portions 312 are formed by photolithography and etching such that the bottom surfaces of the recessed portions 312 are present in the n-type nitride semiconductor layer 305A. Note that the bottom surfaces of the recessed portions 312 may penetrate through the n-type nitride semiconductor layer 305A. Further, at the bottom surfaces of the recessed portion 312, n-side electrodes 309 are formed.

Then, as shown in FIG. 6(c), grooves 354 are formed using a diamond pen, in the bottom surfaces of the recessed portions 312 to a depth of about several micrometers. The grooves 354 are provided at the boundaries between adjacent chip regions 300B along the c-axis direction [0001] and the a-axis direction [11-20].

Then, as shown in FIG. 6(d), breaking is performed to obtain the nitride semiconductor light-emitting element 300 which is in the form of a chip of a predetermined size. When laser dicing is performed, grooves are formed by laser to a depth of about 50 μm. On the other hand, when mechanical dicing is performed as in FIG. 6, the depth of the grooves 354 is about several micrometers. Thus, when mechanical dicing is performed, the depth of the grooves 354 can be small as compared with the case of laser dicing, so that a surface of high cleavability is likely to emerge. Therefore, the c-plane is likely to emerge as the light extraction surface 311b, and an m-plane which is inclined by 30° with respect to the normal line of the substrate 304A is likely to emerge as the light extraction surfaces 311d.

In the present embodiment, not only a portion of the light extraction surfaces 311d which is formed by the substrate 304 but also another portion of the light extraction surfaces 311d which is formed by the n-type nitride semiconductor layer 305, the nitride semiconductor active layer 306, and the p-type nitride semiconductor layer 307 may be generally parallel to the m-plane that is inclined by 30° with respect to the normal line of the substrate 304A.

The nitride semiconductor light-emitting element 300 shown in FIG. 5(c-1) has such an advantage that a manufacturing method which is based on cleaving is readily applicable.

### Variation 2 of Embodiment 1

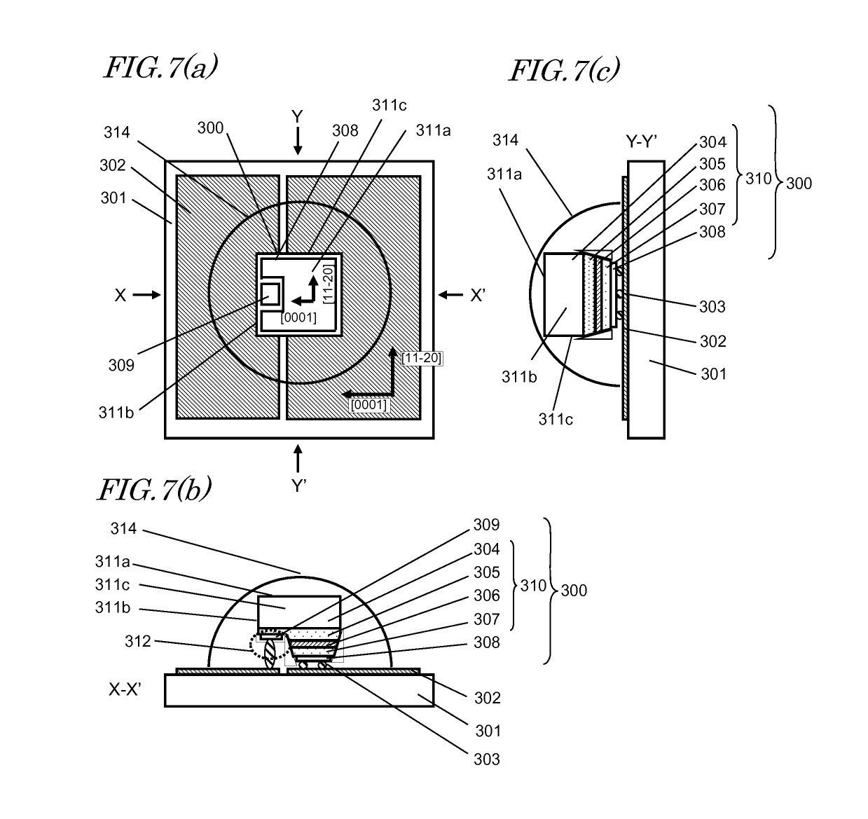

FIG. 7 shows Variation 2 of Embodiment 1. In the description provided below, the features of Embodiment 1 which have already been described above will not be described again.

In Variation 2, the multilayer structure has light extraction surfaces 311a, 311b, and 311c.

The light extraction surfaces 311b and 311c are each formed by the substrate 304, the n-type nitride semiconductor layer 305, the nitride semiconductor active layer 306, and the p-type nitride semiconductor layer 307. A portion of the light extraction surfaces 311b which is formed by the substrate 304 is parallel to the c-plane. Another portion of the light extraction surfaces 311b which is formed by the n-type nitride semiconductor layer 305, the nitride semiconductor active layer 306, and the p-type nitride semiconductor layer 307 is inclined with respect to the normal direction of the light extraction surface 311a (and the c-plane).

A portion of the light extraction surface 311c which is formed by the substrate 304 is parallel to the a-plane. Another portion of the light extraction surface 311c which is formed by the n-type nitride semiconductor layer 305, the nitride semiconductor active layer 306, and the p-type nitride semiconductor layer 307 is inclined with respect to the normal direction of the light extraction surface 311a (and the a-plane). In FIG. 7(c), the light extraction surfaces 311b are inclined such that the width of the light extraction surfaces 311b along the a-axis direction decreases sequentially from the n-type nitride semiconductor layer 305 to the p-type nitride semiconductor layer 307. However, the light extraction surfaces 311b may be inclined in the opposite direction.

The configuration shown in FIG. 7 can be formed by performing etching with a hard mask which has a tapered cross section (tapered such that the width becomes narrower with the increase of the distance from the p-type nitride semiconductor layer 307) being provided on the p-type nitride semiconductor layer 307 of the multilayer structure 310 that is in the form of a wafer. This is because, in this case, the incline of the lateral surface of the hard mask will be reflected in the lateral surface of the multilayer structure 310. By employing such dry etching conditions that provide high reactivity, the cross section can have a tapered shape.

In this variation, in the case where a portion of the light extraction surfaces 311b is inclined, calculation of “the area of the light extraction surfaces 311b” is not carried out on the area of an image which is formed by projection of the inclined surface onto a plane which is parallel to the c-plane but on the area of the inclined surface itself.

In this variation, part of the light extraction surfaces 311b and 311c is inclined with respect to the normal direction of the light extraction surface 311a, so that total reflection is less likely to be repeated inside the nitride semiconductor light-emitting element 300, and the light extraction efficiency improves.

### Variation 3 of Embodiment 1

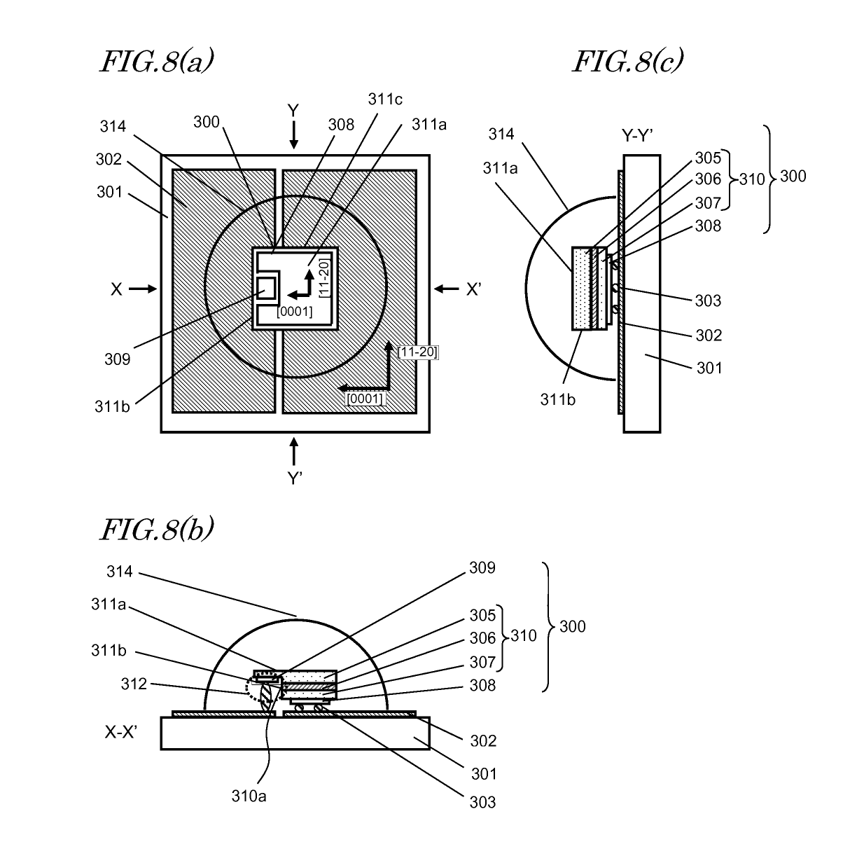

FIG. 8 shows Variation 3 of Embodiment 1. In the description provided below, the features of Embodiment 1 which have already been described above will not be described again.

In Variation 3, the multilayer structure 310 does not include the substrate 304 but includes the n-type nitride semiconductor layer 305, the nitride semiconductor active layer 306, and the p-type nitride semiconductor layer 307. The multilayer structure 310 has light extraction surfaces 311a, 311b, and 311c. The light extraction surface 311a is formed by the n-type nitride semiconductor layer 305. The light extraction surfaces 311b and the light extraction surface 311c are formed by the n-type nitride semiconductor layer 305, the nitride semiconductor active layer 306, and the p-type nitride semiconductor layer 307.

The nitride semiconductor light-emitting element 300 of the present embodiment is manufactured using a substrate which is made of a material different from the nitride semiconductor (heterogeneous substrate), such as a sapphire substrate, a SiC substrate, or a Si substrate. The n-type nitride semiconductor layer 305, the nitride semiconductor active layer 306, the p-type nitride semiconductor layer 307, the p-side electrode 308 and the n-side electrode 309 are formed on a heterogeneous substrate in the form of a wafer, and then, the wafer is separated into respective chips. After a mounting process is performed on the chips, the heterogeneous substrate can be removed using a laser separation method, for example. According to this method, the probability of breakage of the chips in the mounting process can be avoided while the thickness of the element can be reduced by the thickness of the substrate. Thus, the size of the element can be reduced.

### Embodiment 2

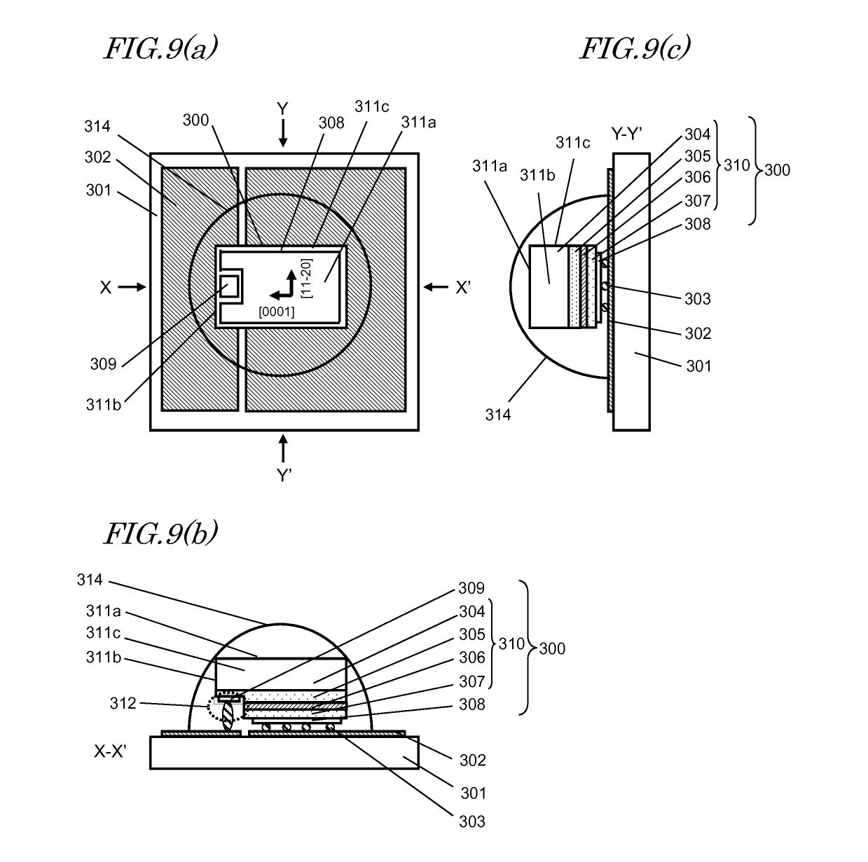

FIG. 9 schematically shows a semiconductor light-emitting device of Embodiment 2. FIG. 9(a) is a top view. FIG. 9(b) is a cross-sectional view taken along line X-X′. FIG. 9(c) is a cross-sectional view taken along line Y-Y′.

The differences of the present embodiment from Embodiment 1 reside in that the length along the c-axis direction of the nitride semiconductor light-emitting element 300 is greater than the length along the a-axis direction of the semiconductor light-emitting element, and that the planar shape of the nitride semiconductor light-emitting element 300 is a rectangular shape. The other features are the same as those of Embodiment 1, and therefore, the detailed descriptions thereof are herein omitted.

When the nitride semiconductor light-emitting element 300 has a square planar shape, it is necessary to reduce the thickness of the substrate 304 in order to configure the area of the light extraction surfaces 311b (the total area of two opposing surfaces) so as to be not more than 44% of the area of the light extraction surface 311a. However, many of substrate materials for use in crystal growth of the nitride semiconductor have high hardness. Thickness reduction by grinding, for example, is difficult in some cases. According to the present embodiment, the nitride semiconductor light-emitting element 300 has a rectangular planar shape where the c-axis direction is the longitudinal direction. Even when the substrate 304 has a large thickness, the areas of the light extraction surfaces 311a and 311b can be controlled by decreasing the length along the a-axis direction of the semiconductor light-emitting element 300.

### Variation of Embodiment 2

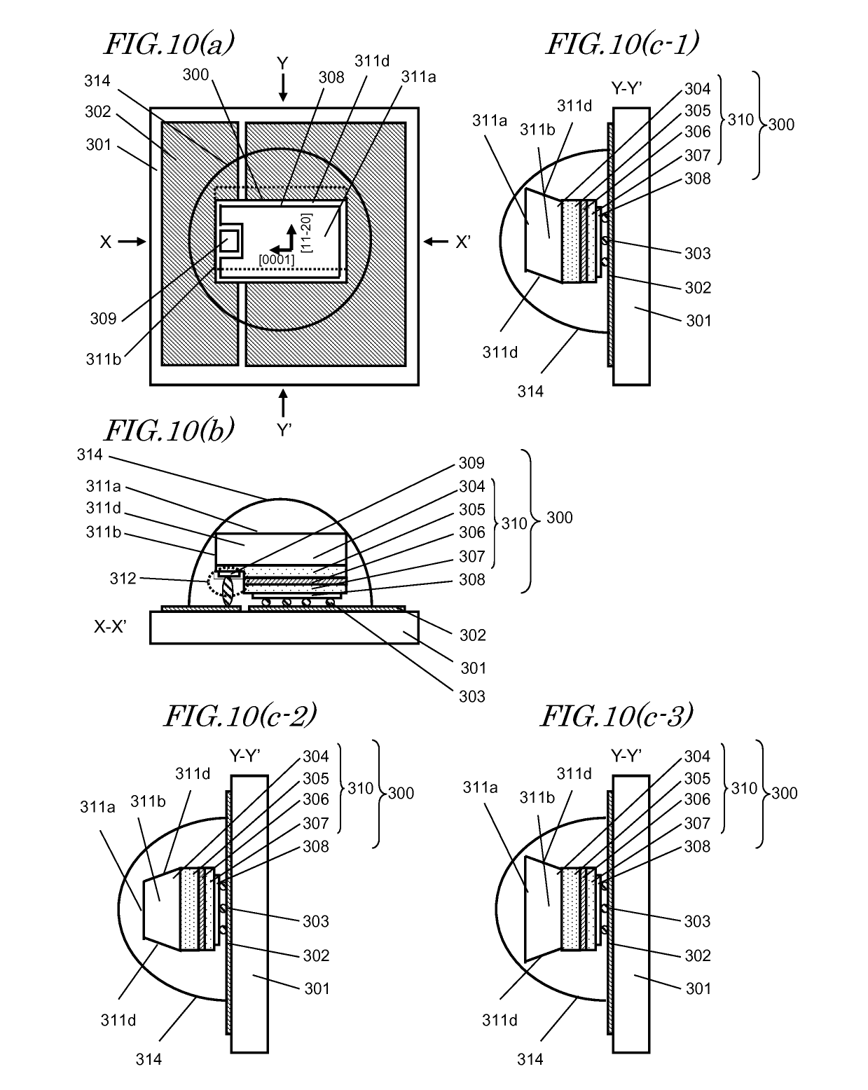

FIG. 10 shows a variation of Embodiment 2.

In the variation, the multilayer structure 310 has light extraction surfaces 311a, 311b, and 311d. The light extraction surfaces 311d include four opposite lateral surfaces and are formed by the substrate 304, the n-type nitride semiconductor layer 305, the nitride semiconductor active layer 306, and the p-type nitride semiconductor layer 307. Of the light extraction surfaces 311d, one or both of two lateral surfaces of the substrate 304 are inclined with respect to the normal direction of the light extraction surface 311a. This incline is, for example, 30°. The surfaces are generally parallel to an m-plane which is different from the m-plane on which the nitride semiconductor active layer 306 has been formed. A portion of the light extraction surfaces 311d which is formed by the n-type nitride semiconductor layer 305, the nitride semiconductor active layer 306, and the p-type nitride semiconductor layer 307 is parallel to the a-plane ((11-20) plane).

In this variation, the nitride semiconductor light-emitting element 300 has a rectangular planar shape as in Embodiment 2. Also, a portion of the light extraction surfaces 311d is generally parallel to the m-plane as in Variation 1 of Embodiment 1. Thus, descriptions of these features are herein omitted.

According to this variation, the light extraction surfaces 311d are inclined with respect to the normal direction of the light extraction surface 311a, and therefore, light reflected inside the nitride semiconductor light-emitting element 300 is more likely to be extracted to the outside, so that the optical output improves. By controlling which m-plane is to be exposed by cleaving, the shapes shown in FIG. 10(c-1), FIG. 10(c-2), and FIG. 10(c-3) can be formed.

Also, in Variations 2 and 3 of Embodiment 1, the nitride semiconductor light-emitting element 300 may have a rectangular planar shape.

### Embodiment 3

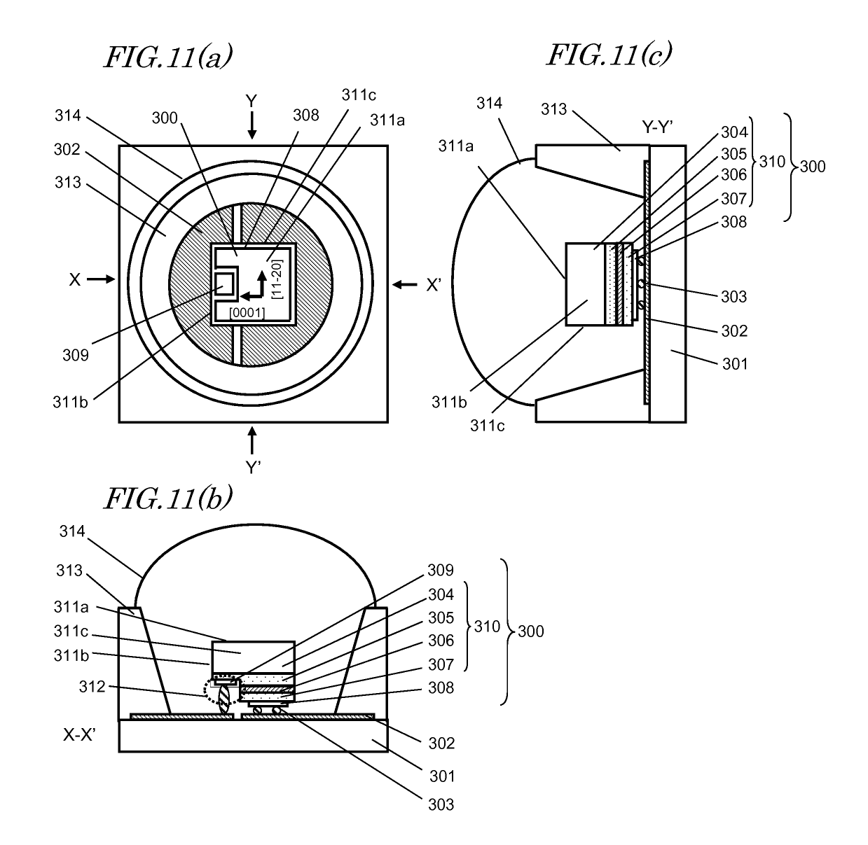

FIG. 11 schematically shows a semiconductor light-emitting device of Embodiment 3. FIG. 11(a) is a top view. FIG. 11(b) is a cross-sectional view taken along line X-X′. FIG. 11(c) is a cross-sectional view taken along line Y-Y′.

The difference of the present embodiment from Embodiment 1 resides in that the surface of the mounting base 301 has a cavity 313. The cavity 313 is a recessed portion formed in the surface of the mounting base 301. At the bottom surface of the recessed portion, the nitride semiconductor light-emitting element 300 is provided. By provision of the cavity 313, light emitted from the nitride semiconductor light-emitting element 300 is reflected, and the light distribution characteristics can be controlled.

The cavity 313 is made of a high reflectance material, whereby the luminous efficacy can be improved. For example, a silicone resin which contains alumina or TiO₂ microparticles may be used. The surface of the cavity 313 may be covered with a high reflectance material, such as Al or Ag. In this variation, the area of the light extraction surfaces 311b (the total area of two opposite surfaces) is not more than 44% of the area of the light extraction surface 311a, so that the average asymmetry degree of the light distribution along the a-axis direction and the light distribution along the c-axis direction can be not more than 6%.

The present embodiment may have a reflector other than the cavity 313.

### Variation 1 of Embodiment 3

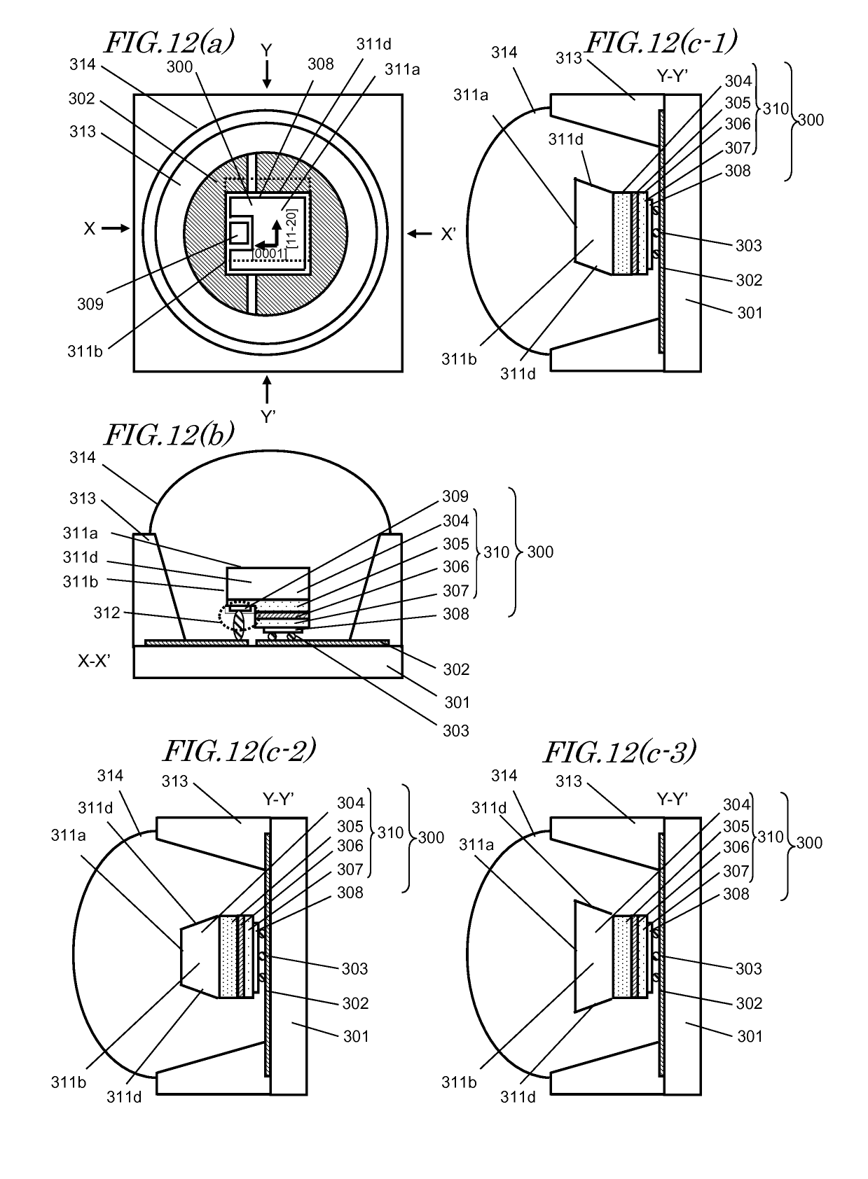

FIG. 12 shows Variation 1 of Embodiment 3.

In Variation 1, the multilayer structure 310 has light extraction surfaces 311a, 311b, and 311d. The light extraction surfaces 311d include four opposite lateral surfaces and are formed by the substrate 304, the n-type nitride semiconductor layer 305, the nitride semiconductor active layer 306, and the p-type nitride semiconductor layer 307. Of the light extraction surfaces 311d, both or one of two lateral surfaces of the substrate 304 is inclined with respect to the normal direction of the light extraction surface 311a. This incline is, for example, 30°. The surfaces are generally parallel to an m-plane which is different from the m-plane on which the nitride semiconductor active layer 306 has been formed. A portion of the light extraction surfaces 311d which is formed by the n-type nitride semiconductor layer 305, the nitride semiconductor active layer 306, and the p-type nitride semiconductor layer 307 is parallel to the a-plane ((11-20) plane).

In this variation, the cavity 313 is provided as in Embodiment 3. Also, a portion of the light extraction surfaces 311d is generally parallel to the m-plane as in Variation 1 of Embodiment 1. Thus, descriptions of these features are herein omitted.

According to this variation, one or a plurality of the light extraction surfaces 311d are inclined with respect to the normal direction of the light extraction surface 311a, and therefore, light reflected inside the nitride semiconductor light-emitting element 300 is more likely to be extracted to the outside, so that the optical output improves. By controlling which m-plane is to be exposed by cleaving, the shapes shown in FIG. 12(c-1), FIG. 12(c-2), and FIG. 12(c-3) can be formed.

In Variations 2 and 3 of Embodiment 1, the cavity 313 may be provided. In Embodiment 2 or the variation of Embodiment 2, the cavity 313 may be provided.

### OTHER EMBODIMENTS

Here, a case where a texture structure is intentionally provided in the light extraction surface 311a is described.

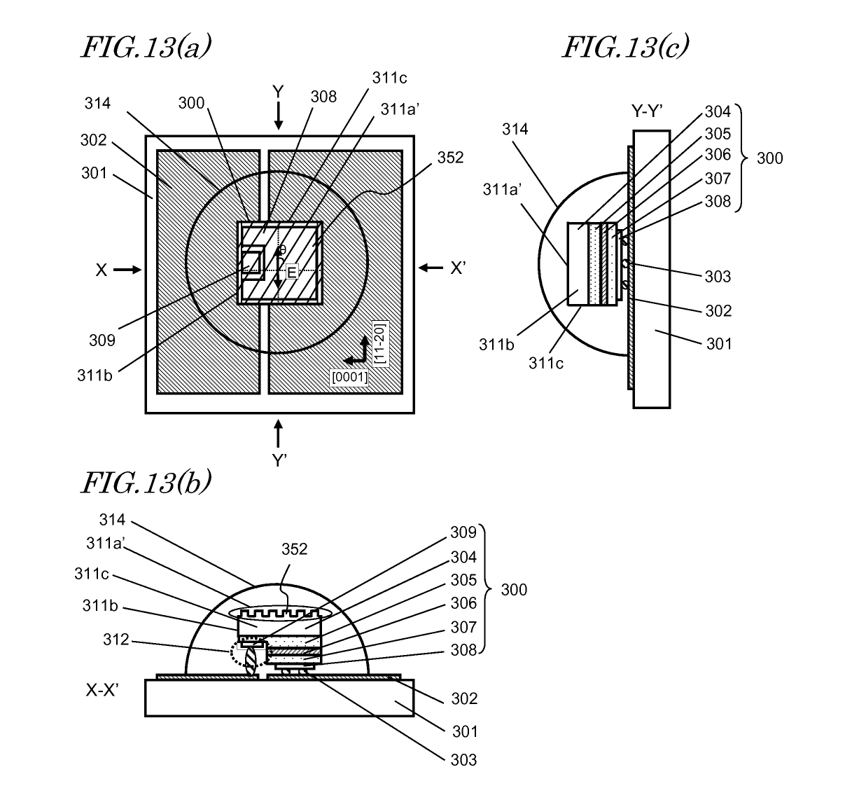

FIG. 13 schematically shows a semiconductor light-emitting device which has a light extraction surface 311a′ in which a texture structure is intentionally provided. FIG. 13(a) is a top view. FIG. 13(b) is a cross-sectional view taken along line X-X′. FIG. 13(c) is a cross-sectional view taken along line Y-Y′.

The light extraction surface 311a′ of the nitride semiconductor light-emitting element 300 shown in FIG. 13 has a plurality of grooves 352 in a stripe arrangement. The extending direction of the grooves 352 is a direction which is inclined by angle θ with respect to the c-plane.

The interval of the grooves 352 may be not less than 300 nm and not more than 8 μm. This is because, when the interval of the grooves 352 is smaller than 300 nm, light would be less likely to be affected by the periodic structure of the grooves 352 and when the interval of the grooves 352 is greater than 8 μm, the number of grooves 352 formed in the light extraction surface 311a′ would be small. In the light extraction surface 311a′, θ (mod 180°) may be not less than 5° and not more than 175° where θ is the absolute value of the angle formed between the extending direction of the stripes and the polarization direction (a-axis direction). Within this angle range, the polarization degree can be effectively reduced. Further, θ (mod 180°) may be not less than 30° and not more than 150°. Within this angle range, the polarization can be more effectively reduced.

In the case where the texture structure is provided in the light extraction surface 311a′, “the area of the light extraction surface 311a′” refers to the area of an image which is formed by projecting the light extraction surface 311a′ onto a plane which is parallel to the m-plane.

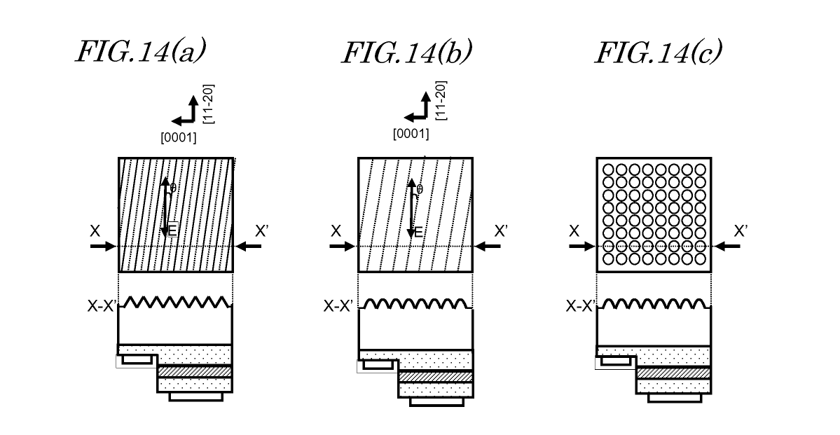

The texture structure is not limited to the pattern shown in FIG. 13(a). For example, as shown in FIG. 14(a), the grooves may have a triangular cross section such that the width is narrower at a deeper position. As shown in FIG. 14(b), the cross section of the grooves may have a curved surface shape. As shown in FIG. 14(c), a plurality of raised portions may be arranged in rows and columns over the light extraction surface 311a′. The shape of the raised portions may be a conical shape or a semicircular shape. The raised portions may not be arranged with equal intervals.

The texture structure of the present embodiment may be formed by performing dry etching after formation of a mask by photolithography on the light extraction surface 311a′. By modifying the dry etching conditions, the cross-sectional shape of the texture structure can be controlled. For example, when such conditions that provide a high physical etching property are employed where the etching pressure is decreased and the ion extraction voltage is increased, a lateral surface which is close to the normal direction of the light extraction surface 311a′ can be formed. On the other hand, when such conditions that provide a high chemical etching property are employed where an ICP plasma source of high plasma density is used and the ion extraction voltage is low, a lateral surface which is inclined with respect to the normal direction of the light extraction surface 311a′ can be formed.

### Inventive Example 1

Hereinafter, Inventive Example 1 is described in which the m-planes were mainly exposed as the light extraction surfaces 311d.

On an m-plane n-type GaN substrate in the form of a wafer, an n-type nitride semiconductor layer formed of an n-type GaN layer having a thickness of 2 μm, a nitride semiconductor active layer which had a quantum well structure consisting of three cycles of 15 nm thick InGaN quantum well layers and 30 nm thick GaN barrier layers, and a p-type nitride semiconductor layer formed of a p-type GaN layer having a thickness of 0.5 μm were formed. Ti/Pt layers were formed as the n-side electrode, and Pd/Pt layers were formed as the p-side electrode. The thickness of the m-plane n-type GaN substrate was reduced by grinding to a predetermined thickness. Grooves were formed using a diamond pen in the wafer along the c-axis direction [0001] and the a-axis direction [11-20] to a depth of about several micrometers from the surface. Thereafter, breaking of the wafer was performed such that the wafer was separated into small chips (nitride semiconductor light-emitting elements 300) of a predetermined size. When the breaking was performed along the c-axis direction [0001], the c-plane was substantially exposed along the scribe lines. On the other hand, when the breaking was performed along the a-axis direction [11-20], the m-plane was exposed in many cases.

The thus-fabricated nitride semiconductor light-emitting element 300 in the form of a chip was flip-chip mounted on the mounting base 301 in which wires were formed on alumina, whereby a semiconductor light-emitting device was manufactured. In order to examine the light distribution characteristics of light emitted from the nitride semiconductor light-emitting element 300, the sealing portion 314 was not formed over the surface of the nitride semiconductor light-emitting element 300.

Table 1 is a list of sizes of the nitride semiconductor light-emitting element 300 and thicknesses of the substrate (GaN substrate) 304 which were used in the semiconductor light-emitting devices. We prepared five types of samples among which the ratio of the area of the light extraction surfaces 311b to the area of the light extraction surface 311a was different. The emission peak wavelengths of these semiconductor light-emitting devices were from 405 nm to 410 nm for the current value of 10 mA.

TABLE 1

| | | | | | Ratio of area of |
|---|---|---|---|---|---|
| | | | | | light extraction |
| | | | Area of | Area of | surfaces 311b |
| | | | light | light | to area of light |
| Sam- | Size of | Substrate | extraction | extraction | extraction |
| ple | one side | thickness | surface | surfaces | surface |
| No. | [μm] | [μm] | 311a [mm²] | 311b [mm²] | 311a [%] |
| 1 | 350 | 100 | 0.1225 | 0.0728 | 59.43 |
| 2 | 450 | 50 | 0.2025 | 0.0486 | 23.56 |
| 3 | 450 | 100 | 0.2025 | 0.0936 | 46.22 |
| 4 | 450 | 150 | 0.2025 | 0.1386 | 68.44 |
| 5 | 950 | 150 | 0.9025 | 0.2926 | 32.42 |

For the five types of semiconductor light-emitting devices shown in Table 1, an electric current of 10 mA was allowed to flow in order to examine the light distribution characteristics. The light distribution characteristics were the results of measurement of the luminous intensity of the light distribution characteristic along the a-axis direction and the light distribution characteristic along the c-axis direction with the use of OL700-30 LED GONIOMETER manufactured by Optronic Laboratories, Inc., based on condition A (the distance between the tip of an LED and the light receiving section 318 is 316 mm), which is described in CIE127 published by the International Commission on Illumination (CIE).

The light distribution characteristic along the a-axis direction refers to a value which was obtained by measuring the luminous intensity while rotating the nitride semiconductor light-emitting element 300 around the c-axis of the nitride semiconductor light-emitting element 300, with the angle formed between the normal direction [1-100] of the m-plane of the nitride semiconductor light-emitting element 300 and the measurement line 319 being the measurement angle.

The light distribution characteristic along the c-axis direction refers to a value which was obtained by measuring the luminous intensity while rotating the nitride semiconductor light-emitting element 300 around the a-axis of the nitride semiconductor light-emitting element 300, with the angle formed between the normal direction [1-100] of the m-plane of the nitride semiconductor light-emitting element 300 and the measurement line 319 being the measurement angle.

Further, to convert the asymmetry of the light distribution along the a-axis direction and the light distribution along the c-axis direction into a numerical expression, the asymmetry degree, the maximum asymmetry degree, and the average asymmetry degree are defined. The asymmetry degree refers to a value which is obtained by normalizing the difference between a luminous intensity in the a-axis direction and a luminous intensity in the c-axis direction at the same angle with respect to the normal direction with a luminous intensity in the normal direction [1-100] of the m-plane that is the principal surface, i.e., a luminous intensity at 0°. This asymmetry degree was defined for respective angles in the range of −90° to +90°. The maximum asymmetry degree refers to the maximum of the asymmetry degree in the range of −90° to +90°. The average asymmetry degree refers to the average of the asymmetry degree for the range of −90° to +90°.

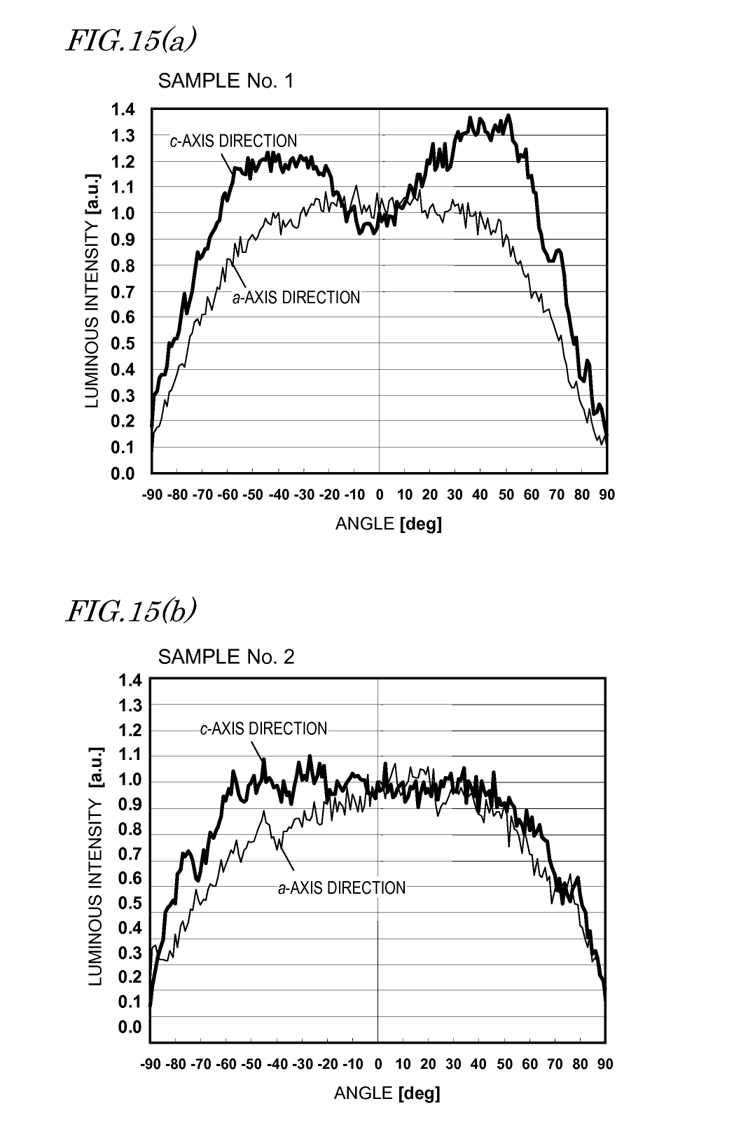

FIG. 15(a) is a graph showing the light distribution characteristic along the a-axis direction (thin solid line) and the light distribution characteristic along the c-axis direction (bold solid line) of the semiconductor light-emitting device of Sample No. 1. The light distribution characteristics are shown together in the same graph where the normal direction of the m-plane that is the principal surface is 0°. The vertical axis represents the luminous intensity (cd) which was normalized with the value at angle 0. The light distribution characteristic along the a-axis direction has such a shape that the maximum value occurs at approximately 0° and the luminous intensity monotonically decreases as the angle increases. On the other hand, the light distribution characteristic along the c-axis direction has such a shape that the maximum value occurs at about ±50°.

FIG. 15(b) is a graph showing the light distribution characteristic along the a-axis direction (thin solid line) and the light distribution characteristic along the c-axis direction (bold solid line) of the semiconductor light-emitting device of Sample No. 2. The light distribution characteristics are shown together in the same graph where the normal direction of the m-plane that is the principal surface is 0°. The vertical axis represents the luminous intensity (cd) which was normalized with the value at angle 0. The light distribution characteristic along the a-axis direction has such a shape that the maximum value occurs at approximately 0° and the luminous intensity monotonically decreases as the angle increases. It can be seen that the peaks at about ±50° which were detected in Sample No. 1 were reduced.

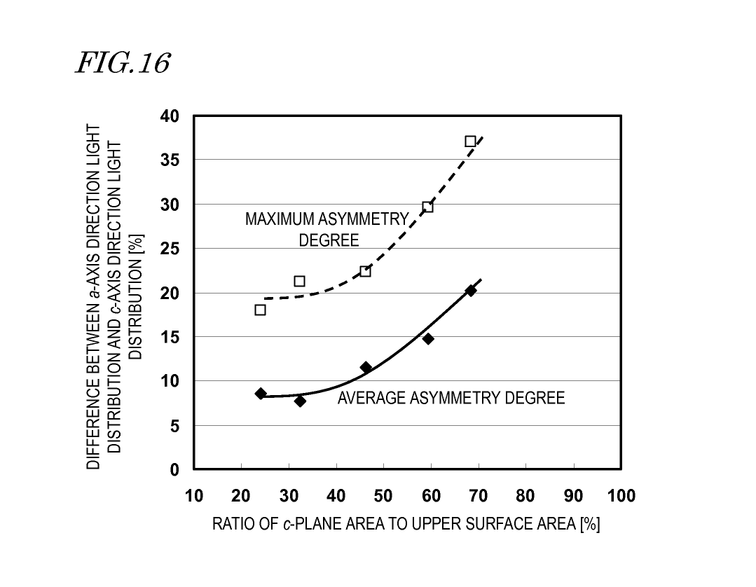

FIG. 16 is a graph showing the ratio of the area of the light extraction surfaces 311b to the area of the light extraction surface 311a [%] over the horizontal axis and the maximum asymmetry degree and the average asymmetry degree over the vertical axis for the five types of semiconductor light-emitting devices specified in Table 1. As the ratio of the area of the light extraction surfaces 311b to the area of the light extraction surface 311a decreases, the maximum asymmetry degree and the average asymmetry degree also decrease together. When the area ratio is 46%, the average asymmetry degree is 12%. When the area ratio is 32%, the average asymmetry degree is 8%. This means that decreasing the area of the light extraction surfaces 311b relative to the area of the light extraction surface 311a can reduce the influence of light emitted from the light extraction surfaces 311b on the light distribution characteristics. However, when the area ratio is about 46%, the tendency toward saturation can be seen. When the area ratio is not more than 32%, the asymmetry degree of the light distribution settles at a constant value. It is considered that this represents the light distribution characteristics of light emitted from the light extraction surface 311a.

It can be seen from the above that the light distribution characteristic along the c-axis direction of a semiconductor light-emitting device which includes a nitride semiconductor light-emitting element which has a nitride-based semiconductor multilayer structure having an m-plane principal surface strongly depends on the ratio of the area of the light extraction surface 311a that is generally parallel to the m-plane to the area of the light extraction surfaces 311b that are generally parallel to the c-plane but hardly depends on the area of the light extraction surfaces 311d. As a result, from the viewpoint of improving the asymmetry of the light distribution characteristic along the c-axis direction and the light distribution characteristic along the a-axis direction, the ratio of the area of the light extraction surfaces 311b to the area of the light extraction surface 311a may be not more than 46%.

### Inventive Example 2

Hereinafter, Inventive Example 2 which had the sealing portion 314 is described.

On an m-plane n-type GaN substrate in the form of a wafer, an n-type nitride semiconductor layer formed of an n-type GaN layer having a thickness of 2 μm, a nitride semiconductor active layer which had a quantum well structure consisting of three cycles of 15 nm thick InGaN quantum well layers and 30 nm thick GaN barrier layers, and a p-type nitride semiconductor layer formed of a p-type GaN layer having a thickness of 0.5 μm were formed. Ti/Pt layers were formed as the n-side electrode, and Pd/Pt layers were formed as the p-side electrode. The thickness of the m-plane n-type GaN substrate was reduced by grinding to a predetermined thickness. Grooves were formed using a diamond pen in the wafer along the c-axis direction [0001] and the a-axis direction [11-20] to a depth of about several micrometers from the surface on the p-type nitride semiconductor layer side. Thereafter, breaking of the wafer was performed such that the wafer was separated into small chips (nitride semiconductor light-emitting elements 300) of a predetermined size. When the breaking was performed along the c-axis direction [0001], the c-plane was substantially exposed along the scribe lines. On the other hand, when the breaking was performed along the a-axis direction [11-20], the m-plane was exposed in many cases.

The thus-fabricated nitride semiconductor light-emitting element 300 in the form of a chip was flip-chip mounted on the mounting base 301 in which wires were formed on alumina, whereby a semiconductor light-emitting device was manufactured. Further, over the surface of the nitride semiconductor light-emitting element 300, a hemispherical sealing portion 314 was formed of a silicone resin so as to have a refractive index of 1.42 and a diameter of 1.2 mm, whereby a semiconductor light-emitting device shown in FIG. 5 was manufactured.

Table 2 is a list of sizes of the nitride semiconductor light-emitting element 300 and thicknesses of the GaN substrate which were used in the semiconductor light-emitting devices. We prepared three types of samples among which the ratio of the area of the light extraction surfaces 311b to the area of the light extraction surface 311a was different. The emission peak wavelengths of these semiconductor light-emitting devices were from 405 nm to 410 nm for the current value of 10 mA.

TABLE 2

| | | | | | Ratio of area of |
|---|---|---|---|---|---|
| | | | | | light extraction |
| | | | Area of | Area of | surfaces 311b |
| | | | light | light | to area of light |
| Sam- | Size of | Substrate | extraction | extraction | extraction |
| ple | one side | thickness | surface | surfaces | surface |
| No. | [μm] | [μm] | 311a [mm²] | 311b [mm²] | 311a [%] |
| 6 | 350 | 100 | 0.1225 | 0.0728 | 59.43 |
| 7 | 450 | 50 | 0.2025 | 0.0486 | 23.56 |
| 8 | 450 | 100 | 0.2025 | 0.0936 | 46.22 |

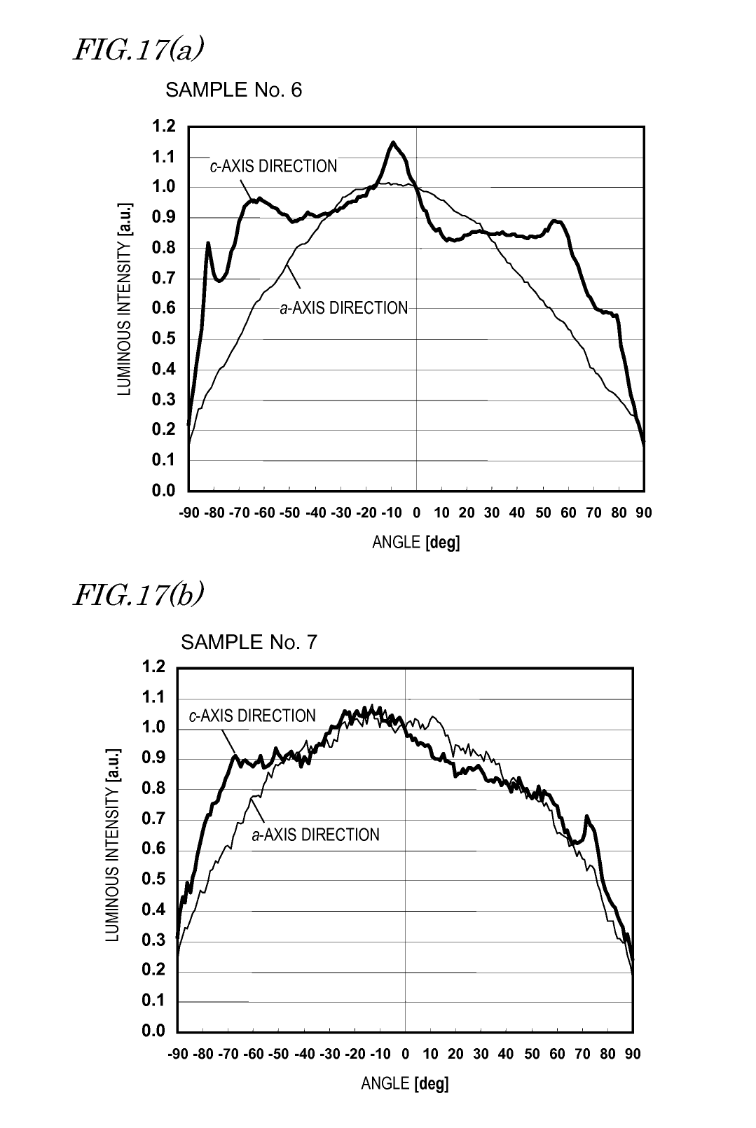

FIG. 17(a) is a graph showing the light distribution characteristic along the a-axis direction (thin solid line) and the light distribution characteristic along the c-axis direction (bold solid line) of the semiconductor light-emitting device of Sample No. 6. The light distribution characteristics are shown together in the same graph where the normal direction of the m-plane that is the principal surface is 0°. The vertical axis represents the luminous intensity (cd) which was normalized with the value at angle 0. The light distribution characteristic along the a-axis direction has such a shape that the maximum value occurs at approximately 0° and the luminous intensity monotonically decreases as the angle increases. On the other hand, the light distribution characteristic along the c-axis direction has a shape which has a plurality of peaks. This result is largely different from the light distribution characteristic along the c-axis direction of Sample No. 1 (FIG. 15(a)). That is, light which is extracted from the nitride semiconductor light-emitting element 300 to the sealing portion 314 is not extracted to the outside with its shape being maintained but is affected by reflection inside the sealing portion 314, reflection by the mounting base 301, and diffraction of light when being extracted from the sealing portion 314 to the outside. As a result, the light distribution characteristic of the semiconductor light-emitting device which has the sealing portion 314 has a further deformed shape as compared with a case where the sealing portion 314 is not provided (FIG. 15(a)).

FIG. 17(b) is a graph showing the light distribution characteristic along the a-axis direction (thin solid line) and the light distribution characteristic along the c-axis direction (bold solid line) of the semiconductor light-emitting device of Sample No. 7. The light distribution characteristics are shown together in the same graph where the normal direction of the m-plane that is the principal surface is 0°. The vertical axis represents the luminous intensity (cd) which was normalized with the value at angle 0. The light distribution characteristic along the a-axis direction has such a shape that the maximum value occurs at approximately 0° and the luminous intensity monotonically decreases as the angle increases. The light distribution characteristic along the c-axis direction has a shape which has a plurality of peaks, but it is not so conspicuous as compared with Sample No. 6. It can be seen that the light distribution characteristic along the a-axis direction (thin solid line) and the light distribution characteristic along the c-axis direction (bold solid line) are closer to each other. It can be seen from the result of FIG. 17(a) that, when the sealing portion 314 is provided, the correlation between the light distribution characteristics of the nitride semiconductor light-emitting element 300 and the sealing portion 314 needs to be considered in designing, and therefore, it is difficult to control the light distribution characteristics of the semiconductor light-emitting device. However, as seen from the result of FIG. 17(b), according to the present embodiment, the light distribution characteristics of the nitride semiconductor light-emitting element 300 are improved, and designing of the sealing portion 314 becomes easy.

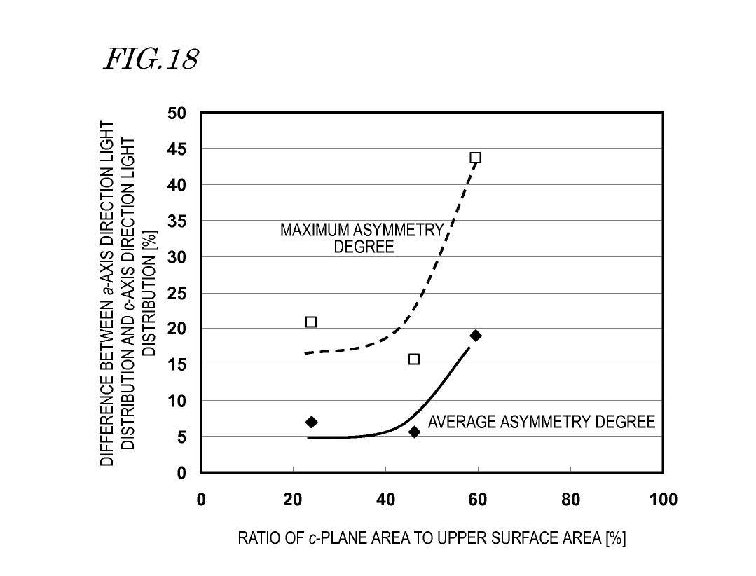

FIG. 18 is a graph showing the ratio of the area of the light extraction surfaces 311b to the area of the light extraction surface 311a [%] over the horizontal axis and the maximum asymmetry degree and the average asymmetry degree over the vertical axis for the three types of semiconductor light-emitting devices specified in Table 2. In samples where the ratio of the area of the light extraction surfaces 311b to the area of the light extraction surface 311a is small, both the maximum asymmetry degree and the average asymmetry degree are small. This means that, even in the nitride semiconductor light-emitting element which has the sealing portion 314, the ratio of the area of the light extraction surfaces 311b to the area of the light extraction surface 311a is decreased, whereby the influence of light emitted from the light extraction surfaces 311b on the light distribution characteristics can be decreased. As in Inventive Example 1, when the ratio of the area of the light extraction surfaces 311b to the area of the light extraction surface 311a is about 46%, decrease of the asymmetry degree exhibits a tendency toward saturation, and when the area ratio is not more than 46%, the asymmetry degree of the light distribution has an approximately constant value. Thus, it can be said that, even in the semiconductor light-emitting device which has the sealing portion 314, the light distribution characteristic along the c-axis direction strongly depends on the ratio of the area of the light extraction surface 311a to the area of the light extraction surfaces 311b.

It can be seen from the above that the light distribution characteristic along the c-axis direction of a semiconductor light-emitting device which includes a nitride semiconductor light-emitting element which has a nitride-based semiconductor multilayer structure having an m-plane principal surface and a sealing portion strongly depends on the ratio of the area of the light extraction surface 311a that is generally parallel to the m-plane to the area of the light extraction surfaces 311b that are generally parallel to the c-plane but hardly depends on the area of the light extraction surfaces 311d. As a result, from the viewpoint of improving the asymmetry of the light distribution characteristic along the c-axis direction and the light distribution characteristic along the a-axis direction, the ratio of the area of the light extraction surfaces 311b to the area of the light extraction surface 311a may be not more than 46%.

### Inventive Example 3

Hereinafter, Inventive Example 3 which had the cavity 313 is described.

On an m-plane n-type GaN substrate in the form of a wafer, an n-type nitride semiconductor layer formed of an n-type GaN layer having a thickness of 2 μm, a nitride semiconductor active layer which had a quantum well structure consisting of three cycles of 15 nm thick InGaN quantum well layers and 30 nm thick GaN barrier layers, and a p-type nitride semiconductor layer formed of a p-type GaN layer having a thickness of 0.5 μm were formed. Ti/Pt layers were formed as the n-side electrode, and Pd/Pt layers were formed as the p-side electrode. The thickness of the m-plane n-type GaN substrate was reduced by grinding to a predetermined thickness. Grooves were formed using a diamond pen in the wafer along the c-axis direction [0001] and the a-axis direction [11-20] to a depth of about several micrometers from the surface on the p-type nitride semiconductor layer side. Thereafter, breaking of the wafer was performed such that the wafer was separated into small chips (nitride semiconductor light-emitting elements 300) of a predetermined size. When the breaking was performed along the c-axis direction [0001], the c-plane was substantially exposed along the scribe lines. On the other hand, when the breaking was performed along the a-axis direction [11-20], the m-plane was exposed in many cases.

The thus-fabricated nitride semiconductor light-emitting element 300 in the form of a chip was flip-chip mounted on the mounting base 301 which had the cavity 313, whereby a semiconductor light-emitting device was manufactured. In order to examine the light distribution characteristics of light emitted from the nitride semiconductor light-emitting element 300, the sealing portion 314 was not formed over the surface of the nitride semiconductor light-emitting element 300. In the cavity 313, the diameter of the bottom portion was 1.2 mm, the diameter of the upper part was 2.2 mm, and the height was 0.5 mm. The slope inside the cavity 313 was inclined by about 45° with respect to the normal direction of the light extraction surface 311a. The cavity 313 was made of a silicone resin and had reflectance of about 90% for light at a wavelength of 405 nm.

Table 3 is a list of sizes of the nitride semiconductor light-emitting element 300 and thicknesses of the substrate (GaN substrate) 304 which were used in the semiconductor light-emitting devices. We prepared three types of samples among which the ratio of the area of the light extraction surfaces 311b to the area of the light extraction surface 311a was different. The emission peak wavelengths of these semiconductor light-emitting devices were from 405 nm to 410 nm for the current value of 10 mA.

TABLE 3

| | | | | | Ratio of area of |
|---|---|---|---|---|---|
| | | | | | light extraction |
| | | | Area of | Area of | surfaces 311b |
| | | | light | light | to area of light |
| Sam- | Size of | Substrate | extraction | extraction | extraction |
| ple | one side | thickness | surface | surfaces | surface |
| No. | [μm] | [μm] | 311a [mm²] | 311b [mm²] | 311a [%] |
| 9 | 350 | 100 | 0.1225 | 0.0728 | 59.43 |
| 10 | 450 | 50 | 0.2025 | 0.0486 | 23.56 |
| 11 | 450 | 100 | 0.2025 | 0.0936 | 46.22 |

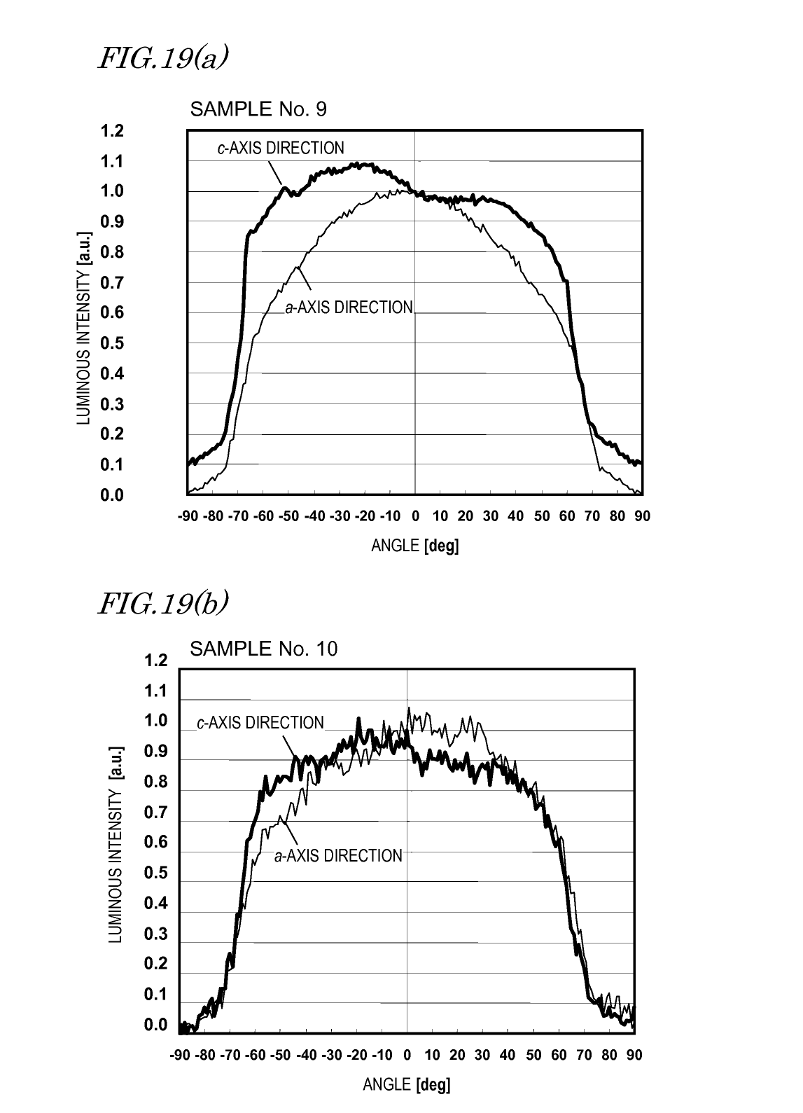

FIG. 19(a) is a graph showing the light distribution characteristic along the a-axis direction (thin solid line) and the light distribution characteristic along the c-axis direction (bold solid line) of the semiconductor light-emitting device of Sample No. 9. The light distribution characteristics are shown together in the same graph where the normal direction of the m-plane that is the principal surface is 0°. The vertical axis represents the luminous intensity (cd) which was normalized with the value at angle 0. The light distribution characteristic along the a-axis direction has such a shape that the maximum value occurs at approximately 0° and the luminous intensity monotonically decreases as the angle increases. On the other hand, the light distribution characteristic along the c-axis direction has such a shape that a peak occurs near ±40°. Since the cavity 313 is provided, the luminous intensity sharply decreases on a large angle side which is not less than 60°.

FIG. 19(b) is a graph showing the light distribution characteristic along the a-axis direction (thin solid line) and the light distribution characteristic along the c-axis direction (bold solid line) of the semiconductor light-emitting device of Sample No. 10. The light distribution characteristics are shown together in the same graph where the normal direction of the m-plane that is the principal surface is 0°. The vertical axis represents the luminous intensity (cd) which was normalized with the value at angle 0. The light distribution characteristics along the a-axis direction and the c-axis direction have such a shape that the maximum value occurs at approximately 0° and the luminous intensity monotonically decreases as the angle increases.

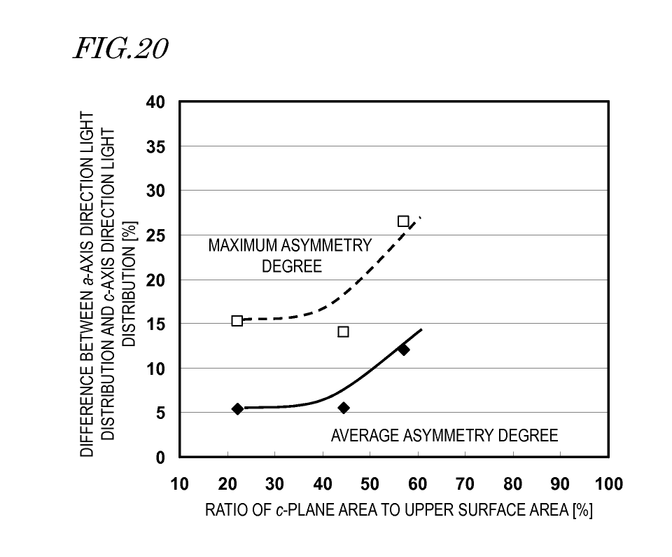

FIG. 20 is a graph showing the ratio of the area of the light extraction surfaces 311b to the area of the light extraction surface 311a [%] over the horizontal axis and the maximum asymmetry degree and the average asymmetry degree over the vertical axis for the three types of semiconductor light-emitting devices specified in Table 3. In samples where the ratio of the area of the light extraction surfaces 311b to the area of the light extraction surface 311a is small, both the maximum asymmetry degree and the average asymmetry degree are small. This means that, even in the semiconductor light-emitting device which has the cavity 313, the ratio of the area of the light extraction surfaces 311b to the area of the light extraction surface 311a is decreased, whereby the influence of light emitted from the light extraction surfaces 311b on the light distribution characteristics can be decreased. As in Inventive Example 1, when the ratio of the area of the light extraction surfaces 311b to the area of the light extraction surface 311a is about 46%, the asymmetry degree exhibits a tendency toward saturation, and when the area ratio is not more than 46%, the asymmetry degree of the light distribution has an approximately constant value. It can be said from the above that, even in the semiconductor light-emitting device which has the cavity 313, the light distribution characteristic along the c-axis direction strongly depends on the ratio of the area of the light extraction surface 311a to the area of the light extraction surfaces 311b.

When compared with the results of FIG. 16 of Inventive Example 1, it can be seen that the asymmetry degree is small as a whole. This is probably because when light emitted from the nitride semiconductor light-emitting element 300 is reflected by the cavity 313, the light is scattered, so that the asymmetry degree is improved.

It can be seen from the above that the light distribution characteristic along the c-axis direction of a semiconductor light-emitting device which includes a nitride semiconductor light-emitting element which has a nitride-based semiconductor multilayer structure having an m-plane principal surface and a cavity strongly depends on the ratio of the area of the light extraction surface 311a that is generally parallel to the m-plane to the area of the light extraction surfaces 311b that are generally parallel to the c-plane but hardly depends on the area of the light extraction surfaces 311d. As a result, from the viewpoint of improving the asymmetry of the light distribution characteristic along the c-axis direction and the light distribution characteristic along the a-axis direction, the ratio of the area of the light extraction surfaces 311b to the area of the light extraction surface 311a may be not more than 46%.

### Inventive Example 4

Hereinafter, Inventive Example 4 is described in which the a-plane was mainly exposed as the light extraction surface 311c.

On an m-plane n-type GaN substrate in the form of a wafer, an n-type nitride semiconductor layer formed of an n-type GaN layer having a thickness of 2 μm, a nitride semiconductor active layer which had a quantum well structure consisting of three cycles of 15 nm thick InGaN quantum well layers and 30 nm thick GaN barrier layers, and a p-type nitride semiconductor layer formed of a p-type GaN layer having a thickness of 0.5 μm were formed. Ti/Pt layers were formed as the n-side electrode, and Pd/Pt layers were formed as the p-side electrode. The thickness of the m-plane n-type GaN substrate was reduced by grinding to a predetermined thickness. Grooves were formed by laser in the wafer along the c-axis direction [0001] and the a-axis direction [11-20] to a depth of about 50 μm from the surface of the n-type GaN substrate. Thereafter, breaking of the wafer was performed such that the wafer was separated into small chips (nitride semiconductor light-emitting elements 300) of a predetermined size. When the breaking was performed along the c-axis direction [0001], the c-plane was exposed. When the breaking was performed along the a-axis direction [11-20], the a-plane was exposed in many cases.

The thus-fabricated nitride semiconductor light-emitting element 300 in the form of a chip was flip-chip mounted on the mounting base 301 in which wires were formed on alumina, whereby a semiconductor light-emitting device was manufactured. In order to examine the light distribution characteristics of light emitted from the nitride semiconductor light-emitting element 300, the sealing portion 314 was not formed over the surface of the nitride semiconductor light-emitting element 300.

Table 4 is a list of sizes of the manufactured semiconductor light-emitting device and thicknesses of the GaN substrate. We prepared two types of samples among which the ratio of the area of the light extraction surfaces 311b to the area of the light extraction surface 311a was different. The emission peak wavelengths of these semiconductor light-emitting devices were from 405 nm to 410 nm for the current value of 10 mA.

TABLE 4

| | | | | | Ratio of area of |
|---|---|---|---|---|---|
| | | | | | light extraction |
| | | | Area of | Area of | surfaces 311b |
| | | | light | light | to area of light |
| Sam- | Size of | Substrate | extraction | extraction | extraction |
| ple | one side | thickness | surface | surfaces | surface |
| No. | [μm] | [μm] | 311a [mm²] | 311b [mm²] | 311a [%] |
| 12 | 450 | 150 | 0.2025 | 0.1386 | 68.44 |
| 13 | 950 | 150 | 0.9025 | 0.2926 | 32.42 |

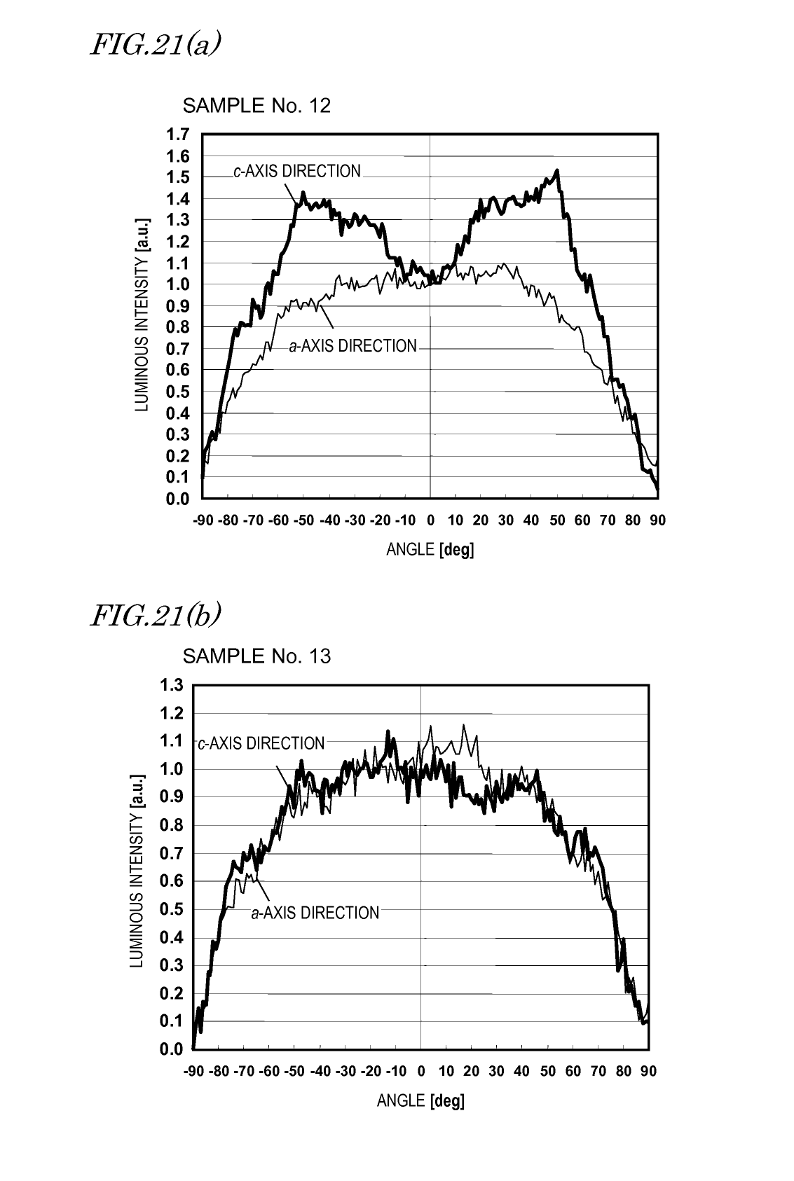

FIG. 21(a) is a graph showing the light distribution characteristic along the a-axis direction (thin solid line) and the light distribution characteristic along the c-axis direction (bold solid line) of the semiconductor light-emitting device of Sample No. 12. The light distribution characteristics are shown together in the same graph where the normal direction of the m-plane that is the principal surface is 0°. The vertical axis represents the luminous intensity (cd) which was normalized with the value at angle 0. Comparing the light distribution characteristics along the c-axis direction of FIG. 15(a) and FIG. 21(a), it is seen that they have substantially equal shapes. Thus, it can be considered that the light distribution characteristic along the c-axis direction is affected by the light extraction surface 311a and the light extraction surfaces 311b.

FIG. 21(b) is a graph showing the light distribution characteristic along the a-axis direction (thin solid line) and the light distribution characteristic along the c-axis direction (bold solid line) of the semiconductor light-emitting device of Sample No. 13. The light distribution characteristics are shown together in the same graph where the normal direction of the m-plane that is the principal surface is 0°. The vertical axis represents the luminous intensity (cd) which was normalized with the value at angle 0. The light distribution characteristics along the a-axis direction and the c-axis direction have such a shape that the maximum value occurs at approximately 0° and that the luminous intensity decreases as the angle increases.

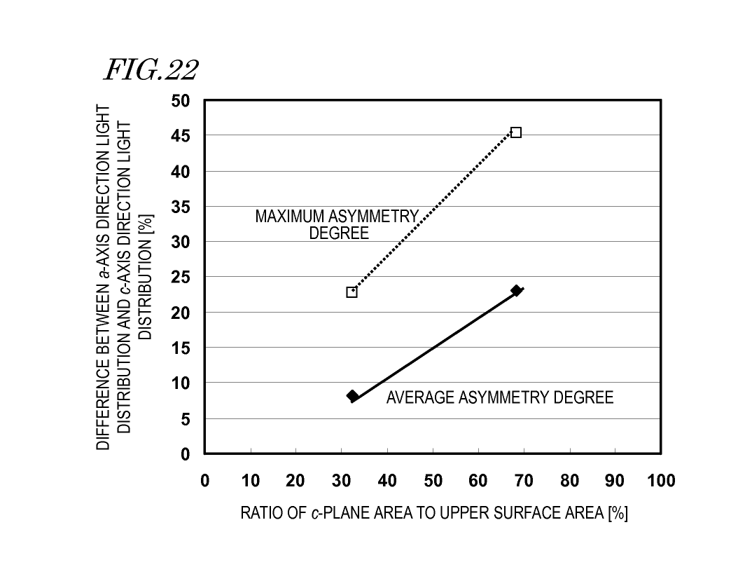

FIG. 22 is a graph showing the ratio of the area of the light extraction surfaces 311b to the area of the light extraction surface 311a [%] over the horizontal axis and the maximum asymmetry degree and the average asymmetry degree over the vertical axis for the two types of semiconductor light-emitting devices specified in Table 4. As the ratio of the area of the light extraction surfaces 311b to the area of the light extraction surface 311a decreases, both the maximum asymmetry degree and the average asymmetry degree also decrease.

When the asymmetry degree is compared between the case of FIG. 16 where the nitride semiconductor light-emitting element had the light extraction surface 311c and the case of FIG. 22 where the nitride semiconductor light-emitting element had the light extraction surfaces 311d, the values of these cases are relatively close to each other. Thus, it can be said that, even in a semiconductor light-emitting device which includes the nitride semiconductor light-emitting element that has the light extraction surfaces 311d, the light distribution characteristic along the c-axis direction strongly depends on the ratio of the area of the light extraction surface 311a to the area of the light extraction surfaces 311b.

With the results of Inventive Examples 1 to 4 being taken into account, it can be considered that the light distribution characteristic along the c-axis direction of the semiconductor light-emitting device that includes the nitride semiconductor light-emitting element 300 depends on the ratio of the area of the light extraction surface 311a that is generally parallel to the m-plane of the nitride semiconductor light-emitting element to the area of the light extraction surfaces 311b that are generally parallel to the c-plane, rather than being affected by the cavity 313, the sealing portion 314, the light extraction surface 311c, and the light extraction surfaces 311d. Such a phenomenon is intrinsic to the light-emitting element formed on the m-plane GaN. Further, from the viewpoint of improving the asymmetry of the light distribution characteristic along the c-axis direction and the light distribution characteristic along the a-axis direction, the ratio of the area of the light extraction surfaces 311b to the area of the light extraction surface 311a may be not more than 46%. The area ratio of not more than 46% specified herein is also a value which is intrinsic to the light-emitting element formed on the m-plane GaN.

### Inventive Example 5

Hereinafter, the plane orientation of a light extraction surface which has undergone laser dicing and mechanical dicing is described.

On an m-plane n-type GaN substrate in the form of a wafer, an n-type nitride semiconductor layer which was formed of an n-type GaN layer having a thickness of 2 μm, a nitride semiconductor active layer which had a quantum well structure consisting of nine cycles of 15 nm thick InGaN quantum well layers and 30 nm thick GaN barrier layers, and a 0.5 μm thick p-type GaN layer were formed. Ti/Pt layers were formed as the n-side electrode, and Mg/Pt layers were formed as the p-side electrode. The thickness of the m-plane n-type GaN substrate was reduced to 150 μm by grinding. The ground wafer was separated into 950 μm-square small chips. In the separation, two types of methods, laser dicing and mechanical dicing, were employed.

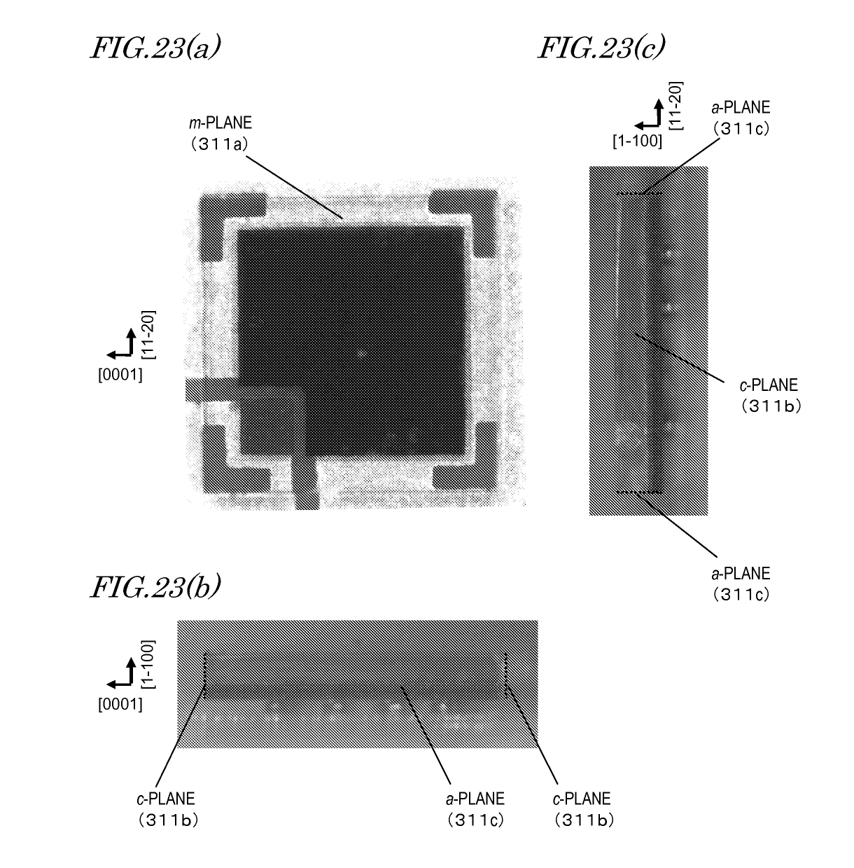

In laser dicing, grooves were formed by laser in the wafer along the c-axis direction [0001] and the a-axis direction [11-20] to a depth of about 50 μm from the surface on the n-type GaN substrate side, and thereafter, breaking of the wafer was performed such that the wafer was separated into small chips. FIG. 23 shows optical microscope images of a nitride-based semiconductor light-emitting element which was separated by laser dicing. FIG. 23(a) is an optical microscope image observed from the light extraction surface 311a side. FIG. 23(b) is an optical microscope image observed from the light extraction surface 311c side. FIG. 23(c) is an optical microscope image observed from the light extraction surface 311b side. Since the light extraction surfaces 311b and 311c formed by laser dicing are generally perpendicular to the light extraction surface 311a that is the m-plane, it is considered that the light extraction surfaces 311b correspond to the c-plane, and the light extraction surface 311c corresponds to the a-plane. In such formation of grooves by laser, the grooves formed in the surface of the n-type GaN substrate have a large depth so that cleaving along the groove direction is easy. Thus, when the grooves were formed parallel to the a-plane and the c-plane, the a-plane and the c-plane were also exposed after breaking.

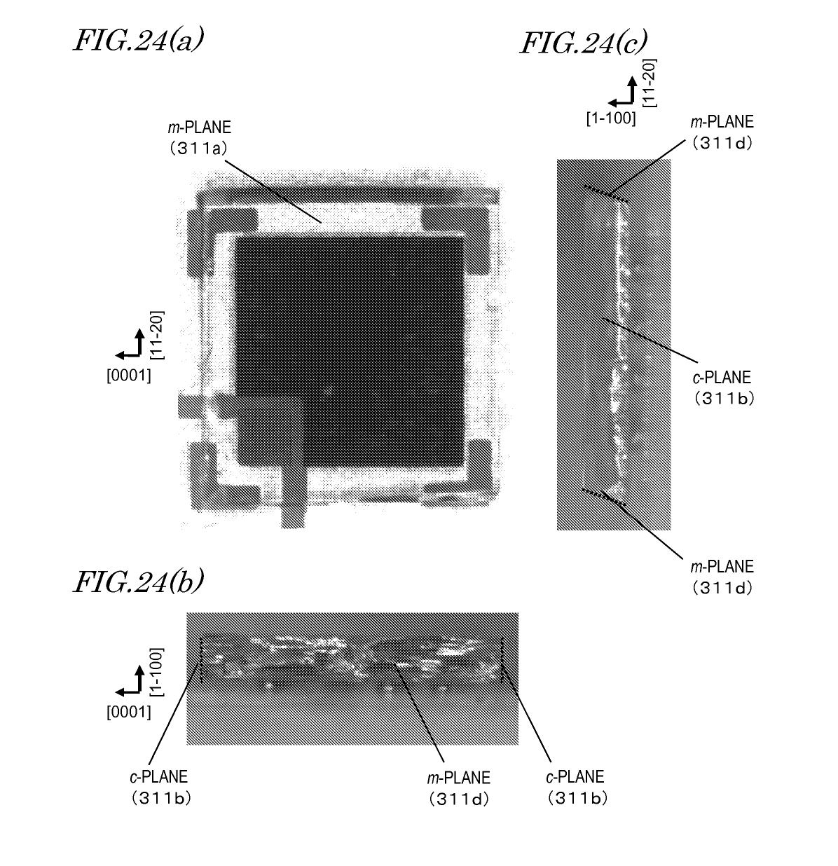

In mechanical dicing, grooves were formed using a diamond pen in the wafer along the c-axis direction [0001] and the a-axis direction [11-20] to a depth of about several micrometers from the surface on the n-type GaN substrate side, and thereafter, breaking of the wafer was performed such that the wafer was separated into small chips. FIG. 24 shows optical microscope images of a nitride-based semiconductor light-emitting element which was separated by mechanical dicing. FIG. 24(a) is an optical microscope image observed from the light extraction surface 311a side. FIG. 24(b) is an optical microscope image observed from the light extraction surface 311d side. FIG. 24(c) is an optical microscope image observed from the light extraction surface 311b side. Since the light extraction surfaces 311b formed by laser dicing are generally perpendicular to the light extraction surface 311a, it is considered that the light extraction surfaces 311b correspond to the c-plane. On the other hand, since the light extraction surface 311d is inclined by about 30° with respect to the normal direction of the light extraction surface 311a that is the m-plane, it is considered that the light extraction surface 311d is the en-plane. In formation of grooves with a diamond pen, the grooves formed in the surface of the n-type GaN substrate have a small depth so that the grooves function as the starting points of cleaving, and as a result, a plane which is readily cleavable is likely to be exposed. Thus, the en-plane and the c-plane, which have high cleavability, were exposed.

These nitride semiconductor light-emitting elements 300 in the form of chips were mounted (flip-chip mounted) on the mounting base 301 in which the wire 302 was formed on alumina, whereby a semiconductor light-emitting devices were manufactured.

In a semiconductor light-emitting device including the nitride semiconductor light-emitting element separated by mechanical dicing, the optical output which was gained by electric current injection of 100 mA exhibited improvement of 35% as compared with a semiconductor light-emitting device including the nitride semiconductor light-emitting element separated by laser dicing.

### Comparative Example 1

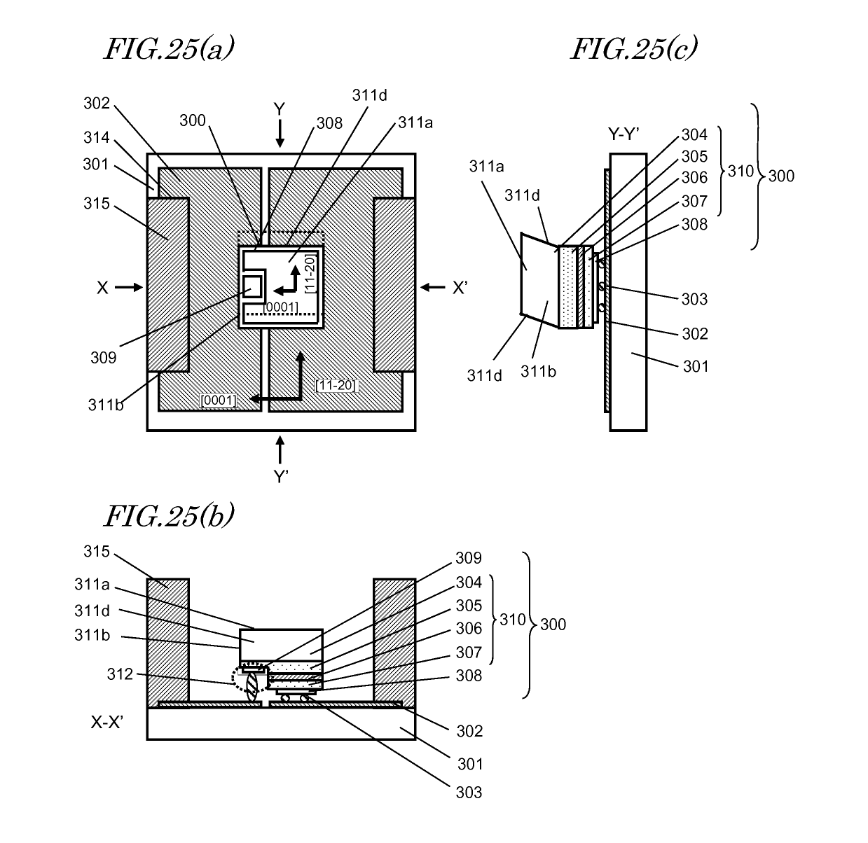

A semiconductor light-emitting device was manufactured by providing shielding plates 315 so as to face the light extraction surfaces 311b of Sample 1 of Inventive Example 1. FIG. 25 is a diagram showing a semiconductor light-emitting device of Comparative Example 1. The difference from FIG. 5 resides in that the shielding plates 315 were provided. The shielding plates 315 were made of black vinyl chloride and had a reflectance of about 4% and a height of 0.5 mm. The shielding plates 315 were provided at positions about 0.5 mm distant from the light extraction surfaces 311b.

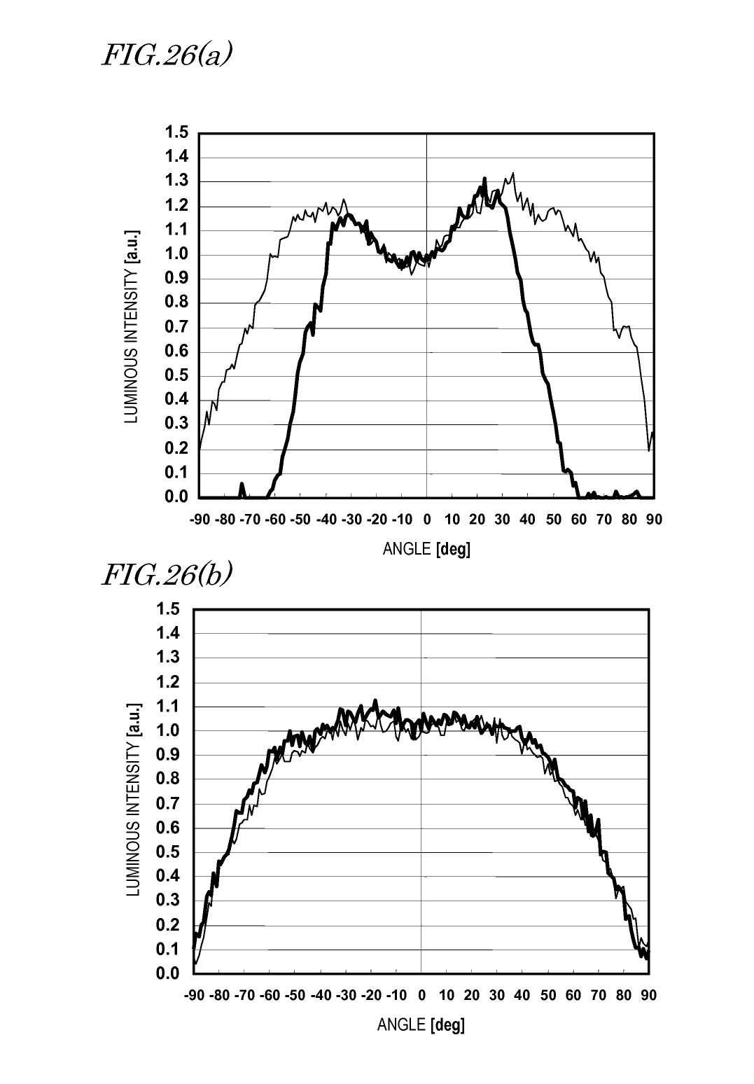

The purpose of Comparative Example 1 is to block light emitted from the surfaces 311b by the shielding plates 315 in order to improve the light distribution characteristic along the c-axis direction. FIG. 26(a) is a graph showing the light distribution characteristic along the c-axis direction. FIG. 26(b) is a graph showing the light distribution characteristic along the a-axis direction. In these graphs, the thin solid line represents the light distribution characteristic which was obtained without the shielding plates 315, and the bold solid line represents the light distribution characteristic which was obtained with the shielding plates 315. In the light distribution characteristics along the c-axis direction (FIG. 26(a)), it can be seen that, with the shielding plates 315 being provided, light was blocked on the large angle sides exceeding ±40°. However, in the range of −40° to +40°, the light distribution characteristic along the c-axis direction was generally constant irrespective of whether or not the shielding plates 315 were provided. The asymmetry degree of the light distribution characteristics along the a-axis direction and the c-axis direction was not improved.

### Comparative Example 2

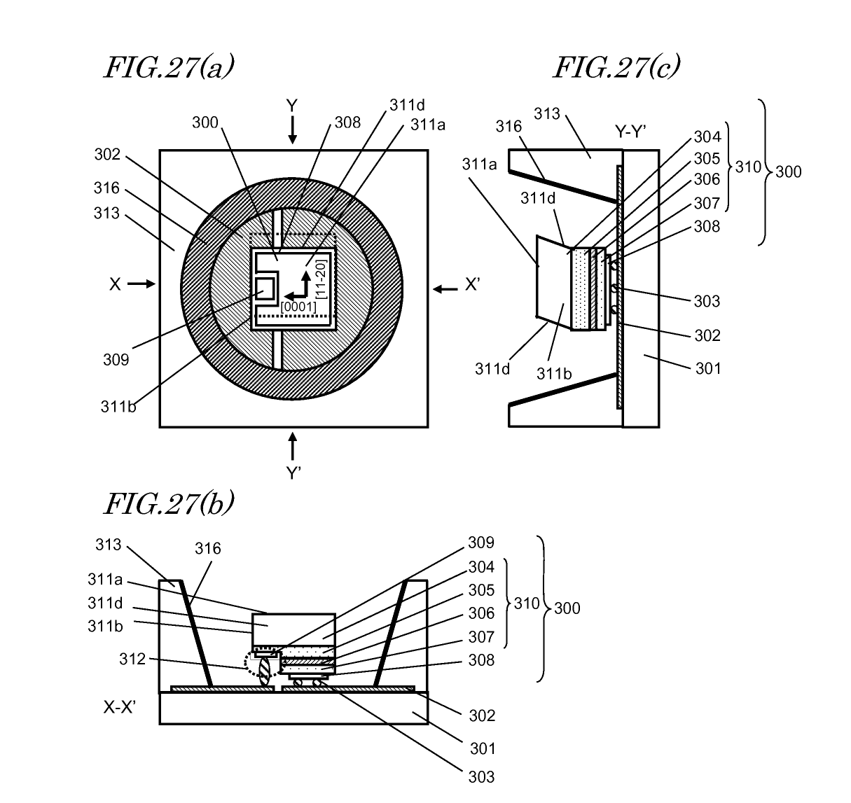

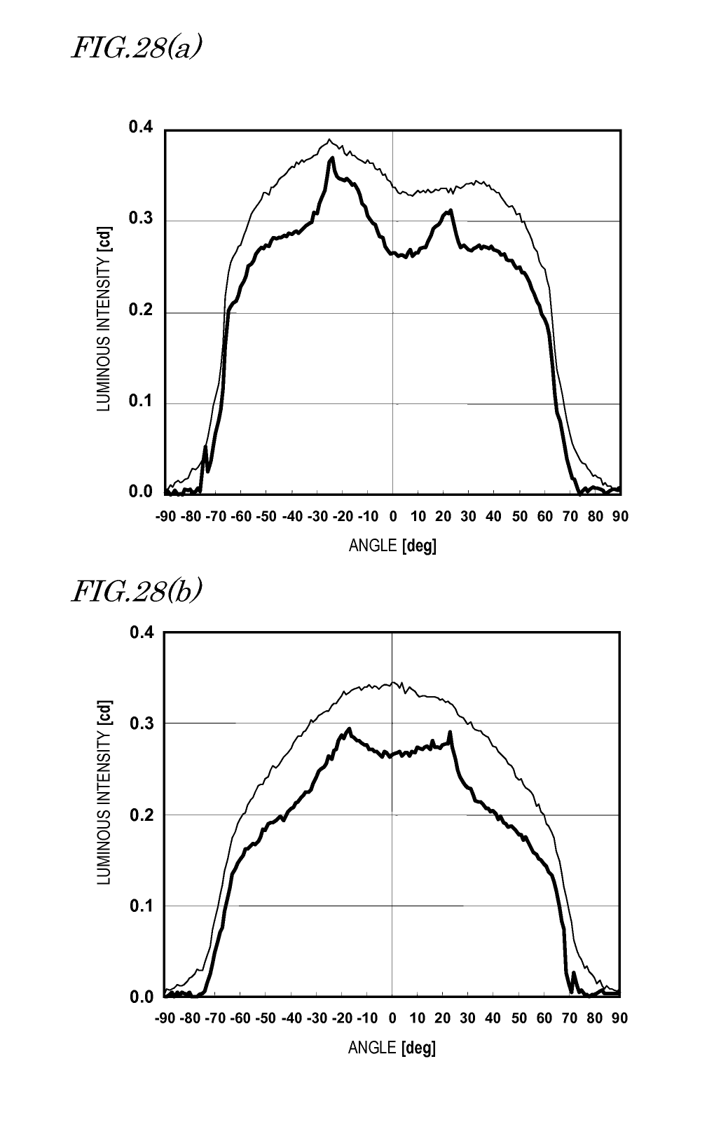

A semiconductor light-emitting device was manufactured by coating the slope surfaces (inner lateral surfaces) of the cavity 313 of Sample 11 of Inventive Example with black ink. FIG. 27 shows a semiconductor light-emitting device of Comparative Example 2. The difference from FIG. 10 resides in that it had a black ink coating region 316. With the black ink coating, the reflectance of the surface of the cavity 313 decreases to about 3%. FIG. 28(a) is a graph showing the light distribution characteristic along the c-axis direction. FIG. 28(b) is a graph showing the light distribution characteristic along the a-axis direction. In these graphs, the thin solid line represents the light distribution characteristic which was obtained without the black ink coating, and the bold solid line represents the light distribution characteristic which was obtained with the black ink coating. FIGS. 28(a) and 28(b) are different from the previously-described graphs of the light distribution characteristics in that the value of the vertical axis is a measured luminous intensity value itself. It can be seen that, with the black ink coating, in both the light distribution characteristic along the a-axis direction and the light distribution characteristic along the c-axis direction, the luminous intensity decreased over the entire angle range. Inventive Example 3 that had the cavity 313 exhibited improved asymmetry degree as compared with Inventive Example 1 that did not have the cavity 313. This is because the cavity 313 has such a property that affects the entire angle range of the light distribution characteristics of the nitride semiconductor light-emitting element. However, when the reflectance of the cavity 313 was changed by the black ink coating, the light distribution characteristics had further deformed shape. That is, since the light distribution characteristics are determined by synthesis of light directly extracted from the nitride semiconductor light-emitting element 300 and light reflected by the cavity 313, designing of the cavity 313 is difficult when the light distribution characteristics of light emitted from the nitride semiconductor light-emitting element 300 are deformed.

### (Differences between Embodiments of Present Invention and Prior Art)

Next, the differences between the embodiments of the present invention and the prior art are described.

In a nitride semiconductor light-emitting element described in Patent Document 1, the polarization characteristics are maintained high, and therefore, the emission intensity is large in a direction perpendicular to the polarization direction. As a result, the light distribution is asymmetric.

A configuration which is capable of solving the above problem is disclosed in Patent Document 2. The first embodiment of Patent Document 2 discloses that four light-emitting diode chips are arranged in different orientations in a package, but the mounting step is complicated. The second embodiment of Patent Document 2 discloses that an uneven shape is formed in a reflective lateral surface of a package, but designing and manufacture of the package are complicated. The third embodiment of Patent Document 2 discloses that an uneven shape is provided in the surface of a light-emitting diode chip. However, the step of forming unevenness is added, and accordingly, manufacture is complicated. The fourth embodiment of Patent Document 2 discloses that an uneven shape extending in a predetermined direction is provided in a light emitting surface of a resin mold of a package. However, designing and manufacture of the resin mold are complicated. The fifth embodiment of Patent Document 2 discloses that a light emitting surface of a package is configured such that the direction of light is changed to an azimuth angle direction where the emission intensity is small. However, designing and manufacture of the resin mold are complicated.

On the other hand, according to the embodiments of the present invention, the asymmetry of the light distribution characteristics along the a-axis direction and the c-axis direction of a semiconductor light-emitting device which includes a semiconductor light-emitting element which has a nitride-based semiconductor multilayer structure having an m-plane principal surface can be improved by a simple configuration.

In a semiconductor light-emitting device of the present embodiment, the light distribution characteristic relative to the axial direction would not vary even when the installation orientation is varied. Thus, this semiconductor light-emitting device can be used for decorative illumination and lighting devices.

### INDUSTRIAL APPLICABILITY

The present invention is applicable to, for example, decorative illumination and lighting devices. Application to the fields of display and optical data processing, for example, has also been expected.

### REFERENCE SIGNS LIST

300 nitride-based semiconductor light-emitting element
300A wafer
300B chip region
301 mounting base
302 wire
303 bump
304, 304A substrate
305, 305A n-type nitride semiconductor layer
306, 306A nitride semiconductor active layer
307, 307A p-type nitride semiconductor layer
308 p-side electrode
309 n-side electrode
310, 301A multilayer structure
311, 311a, 311a′, 311b, 311c, 311d light extraction surface
312 recessed portion
312a lateral surface
313 cavity
314 sealing portion
315 shielding plate
316 black ink coating region
318 light receiving section
319 measurement line
320 transparent sealing portion
352, 354 groove

1. A method for emitting light from a nitride semiconductor light-emitting element, the method comprising:
(a) applying a voltage to the nitride semiconductor light-emitting element comprising an active layer to emit the light from the active layer;
wherein
the nitride semiconductor light-emitting element comprises a multilayer structure;
the multilayer structure includes an n-type nitride semiconductor layer, a p-type nitride semiconductor layer, and the active layer which is made of an m-plane nitride semiconductor and interposed between the n-type nitride semiconductor layer and the p-type nitride semiconductor layer;
the multilayer structure has a first light extraction surface which is parallel to an m-plane in the active layer and a plurality of second light extraction surfaces which are parallel to a c-plane in the active layer;
a ratio of a total area of the plurality of the second light extraction surfaces to an area of the first light extraction surface is not more than 46%; and
an average asymmetry degree of the light distribution along the a-axis direction and the light distribution along the c-axis direction is not more than 12%;
where
the average asymmetry degree refers to an average of an asymmetry degree for the range of −90° to +90°; and
the asymmetry degree refers to a value which is obtained by normalizing the difference between a luminous intensity in the a-axis direction and a luminous intensity in the c-axis direction at the same angle with respect to the normal direction with a luminous intensity in the normal direction [1-100] of the m-plane.

2. The method according to claim 1, wherein
the multilayer structure has one or a plurality of third light extraction surfaces, and
the one or plurality of third light extraction surfaces are inclined with respect to a normal direction of the first light extraction surface.

3. The method according to claim 2, wherein
the one or plurality of third light extraction surfaces are inclined by 30° with respect to the normal direction of the first light extraction surface.

4. The method according to claim 1, wherein
the nitride semiconductor light-emitting element further comprises a substrate;
the substrate has a first surface and a second surface; and
the multilayer structure is formed on or above the first surface of the substrate.

5. The method according to claim 4, wherein
in the step (b), the light is emitted through the second surface of the substrate.

6. The method according to claim 1, wherein
a length along a c-axis direction of the first light extraction surface is greater than a length along an a-axis direction of the first light extraction surface.

7. The method according to claim 1, wherein
a ratio of an area of the second light extraction surface to an area of the first light extraction surface is not less than 24%.

8. The method according to claim 1, wherein
at least any of the first light extraction surface and the plurality of second light extraction surfaces has a texture structure.
